(19) United States
(12) Patent Application Publication
(10) Pub. No.: US 2025/0308941 A1
(43) Pub. Date: Oct. 2, 2025

(54) METHOD FOR MANUFACTURING SEMICONDUCTOR DEVICE AND SEMICONDUCTOR DEVICE

(71) Applicant: Rohm Co., Ltd., Kyoto-shi (JP)

(72) Inventor: Tomohira KIKUCHI, Kyoto-shi (JP)

(21) Appl. No.: 19/085,585

(22) Filed: Mar. 20, 2025

(30) Foreign Application Priority Data
Mar. 26, 2024 (JP) 2024-049434

(51) Int. Cl. H01L 21/56; H01L 23/29; H01L 23/31

(52) U.S. Cl. CPC H01L 21/565; H01L 23/295; H01L 23/3107

(57) ABSTRACT

A method for manufacturing a semiconductor device, the method includes mounting a semiconductor element on a lead frame, placing a mold to position the semiconductor element within a cavity of the mold, forming a resin intermediate by introducing a resin material into the cavity and hardening the resin material, and cutting the lead frame and the resin intermediate. The mold includes: a mold first surface and a mold second surface, a mold third surface, a mold fourth surface, and a mold fifth surface. The mold fifth surface includes a mold first section, a mold second section, and a mold third section. At least a portion of the mold third section is inclined relative to the second direction and the third direction as viewed in the first direction.

### TECHNICAL FIELD

The present disclosure relates to a method for manufacturing a semiconductor device and also to a semiconductor device.

### BACKGROUND ART

JP-A-2022-55599 discloses an example of a conventional semiconductor device. The semiconductor device disclosed in the document includes a semiconductor element, terminals, and a sealing resin. The semiconductor element is covered with the sealing resin. The terminals protrude from the sealing resin. The sealing resin is rectangular.

### BRIEF DESCRIPTIONS OF THE DRAWINGS

FIG. 1 is a plan view of a semiconductor device according to a first embodiment of the present disclosure.

FIG. 2 is a fragmentary plan view of the semiconductor device according to the first embodiment of the present disclosure.

FIG. 3 is a front view of a semiconductor device according to a first embodiment of the present disclosure.

FIG. 4 is a fragmentary enlarged front view of the semiconductor device according to the first embodiment of the present disclosure.

FIG. 5 is a rear view of the semiconductor device according to the first embodiment of the present disclosure.

FIG. 6 is a right-side view of the semiconductor device according to the first embodiment of the present disclosure.

FIG. 7 is a fragmentary enlarged right-side view of the semiconductor device according to the first embodiment of the present disclosure.

FIG. 8 is a left-side view of the semiconductor device according to the first embodiment of the present disclosure.

FIG. 9 is a fragmentary enlarged plan view of the semiconductor device according to the first embodiment of the present disclosure.

FIG. 10 is a sectional view taken along line X-X in FIG. 1.

FIG. 11 is a fragmentary enlarged sectional view of the semiconductor device according to the first embodiment of the present disclosure.

FIG. 12 is a fragmentary enlarged sectional view of the semiconductor device according to the first embodiment of the present disclosure.

FIG. 13 is a fragmentary enlarged sectional view of the semiconductor device according to the first embodiment of the present disclosure.

FIG. 14 is a sectional view taken along line XIV-XIV in FIG. 12.

FIG. 15 is a fragmentary plan view for illustrating a method for manufacturing a semiconductor device according to the first embodiment of the present disclosure.

FIG. 16 is a fragmentary plan view for illustrating the method for manufacturing a semiconductor device according to the first embodiment of the present disclosure.

FIG. 17 is a fragmentary sectional view for illustrating the method for manufacturing a semiconductor device according to the first embodiment of the present disclosure.

FIG. 18 is a fragmentary sectional view for illustrating the method for manufacturing a semiconductor device according to the first embodiment of the present disclosure.

FIG. 19 is a fragmentary enlarged plan view for illustrating the method for manufacturing a semiconductor device according to the first embodiment of the present disclosure.

FIG. 20 is a fragmentary enlarged sectional view taken along line XX-XX in FIG. 19.

FIG. 21 is a fragmentary enlarged sectional view taken along line XXI-XXI in FIG. 19.

FIG. 22 is a fragmentary enlarged sectional view taken along the same line as the sectional view of FIG. 21.

FIG. 23 is a fragmentary enlarged plan view for illustrating the method for manufacturing a semiconductor device according to the first embodiment of the present disclosure.

FIG. 24 is a fragmentary enlarged sectional view taken along line XXIV-XXIV in FIG. 23.

FIG. 25 is a fragmentary enlarged sectional view taken along line XXV-XXV in FIG. 23.

FIG. 26 is a fragmentary enlarged sectional view taken along the same line as the sectional view of FIG. 25.

FIG. 27 is a fragmentary enlarged plan view for illustrating the method for manufacturing a semiconductor device according to the first embodiment of the present disclosure.

FIG. 28 is a fragmentary enlarged sectional view taken along line XXVIII-XXVIII in FIG. 27.

FIG. 29 is a fragmentary enlarged sectional view taken along line XXIX-XXIX in FIG. 27.

FIG. 30 is a fragmentary enlarged plan view for illustrating the method for manufacturing a semiconductor device according to the first embodiment of the present disclosure.

FIG. 31 is a sectional view of a semiconductor device according to a first variation of the first embodiment of the present disclosure.

FIG. 32 is a fragmentary enlarged plan view for illustrating a method for manufacturing a semiconductor device according to a variation of the first embodiment of the present disclosure.

FIG. 33 is a fragmentary enlarged plan view for illustrating a method for manufacturing a semiconductor device according to another variation of the first embodiment of the present disclosure.

FIG. 34 is a fragmentary enlarged plan view for illustrating a method for manufacturing a semiconductor device according to a yet another variation of the first embodiment of the present disclosure.

FIG. 35 is a fragmentary enlarged plan view for illustrating a method for manufacturing a semiconductor device according to a yet another variation of the first embodiment of the present disclosure.

FIG. 36 is a fragmentary enlarged sectional view of a semiconductor device manufactured by the method of the variation shown in FIG. 35.

FIG. 37 is a fragmentary enlarged plan view for illustrating a method for manufacturing a semiconductor device according to a yet another variation of the first embodiment of the present disclosure.

FIG. 38 is a fragmentary enlarged plan view for illustrating a method for manufacturing a semiconductor device according to a yet another variation of the first embodiment of the present disclosure.

FIG. 39 is a fragmentary enlarged plan view for illustrating a method for manufacturing a semiconductor device according to a yet another variation of the first embodiment of the present disclosure.

### DETAILED DESCRIPTION OF EMBODIMENTS

The following describes preferred embodiments of the present disclosure with reference to the drawings.

In the present disclosure, the terms such as “first”, “second”, “third”, and so on are used merely as labels to identify the items referred to by the terms and are not intended to impose a specific order or sequence on these items.

In the description of the present disclosure, the expressions “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expressions “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a portion of the object B”. Still further, “A surface A faces in a direction B (or faces toward a first side or an opposite second side in the direction B) is not limited, unless otherwise specifically noted, to the situation where the surface A forms an angle of 90° with the direction B but includes the situation where the surface A is inclined relative to the direction B.

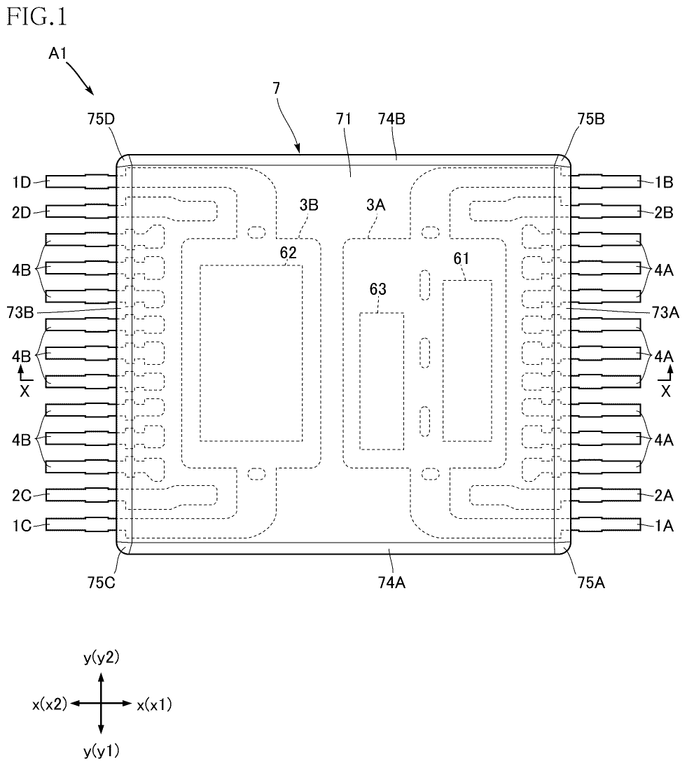

FIGS. 1 to 14 show a semiconductor device according to a first embodiment of the present disclosure. A semiconductor device Al of the present embodiment includes one or more semiconductor elements 60, a first lead 1A, and a sealing resin 7. The semiconductor device A1 may additionally include first leads 1B, 1C, and 1D, second leads 2A, 2B, 2C, and 2D, a first island 3A, a second island 3B, a plurality of leads 4A, a plurality of leads 4B, and wires 81, 82, 83, and 84. The package of the semiconductor device A1 is not specifically limited, suitable examples include SOP (small outline package).

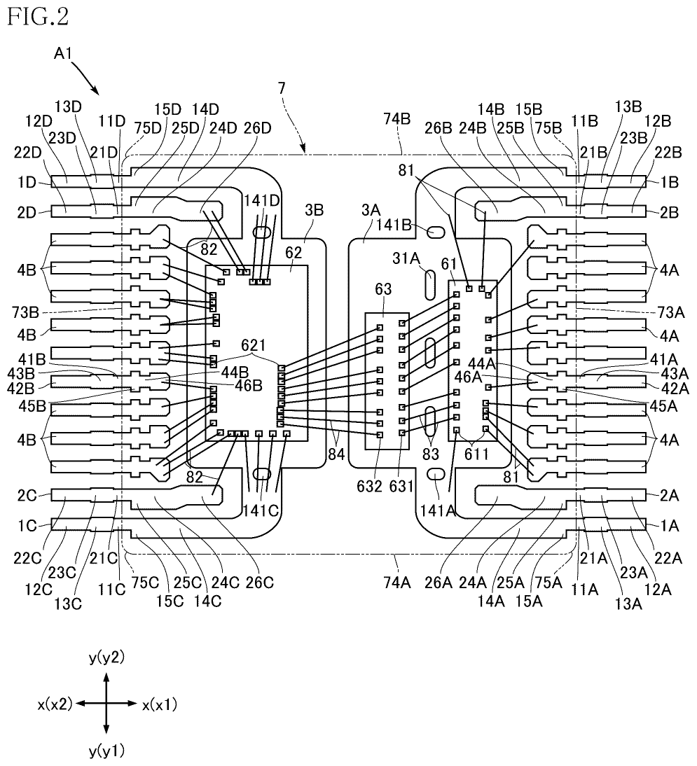

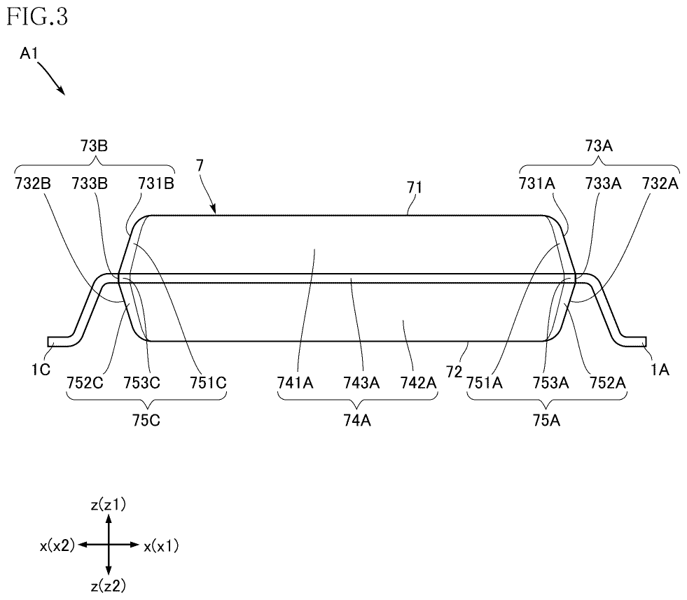

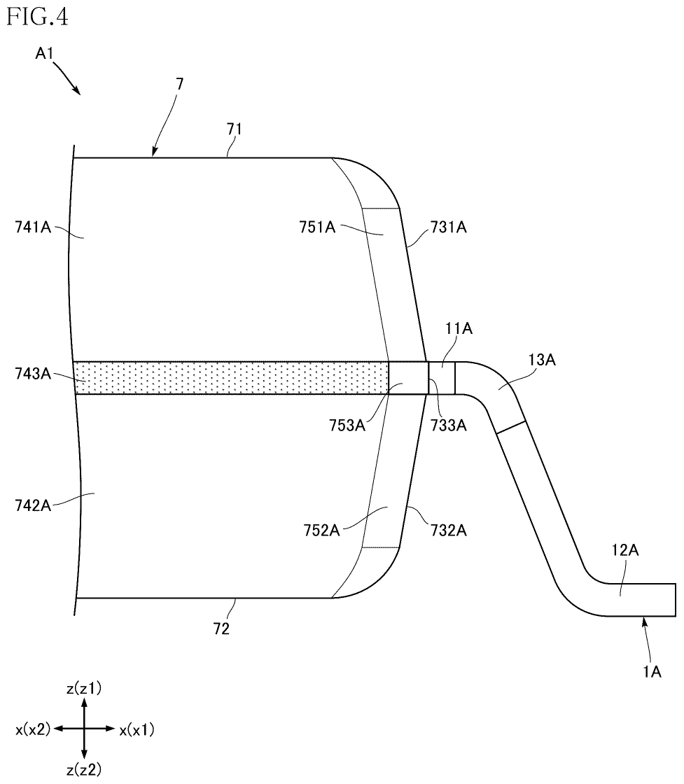

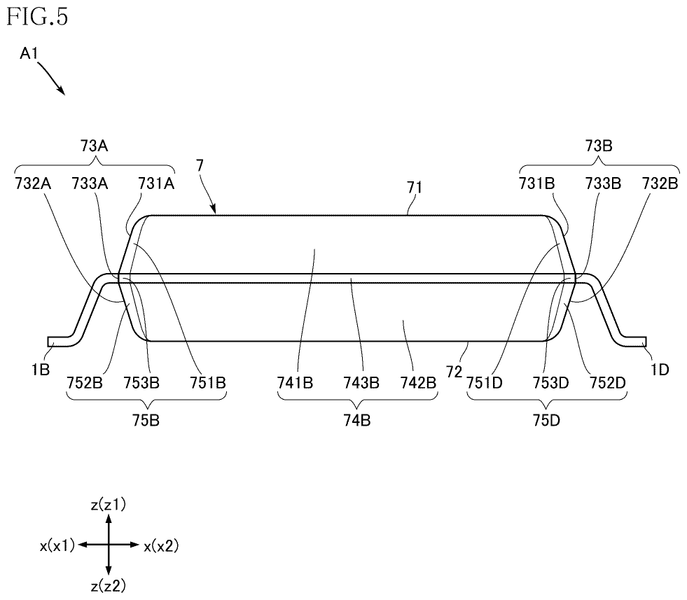

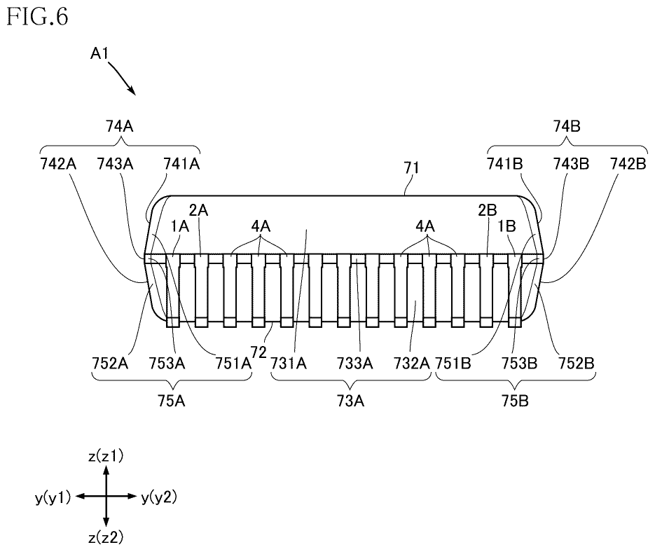

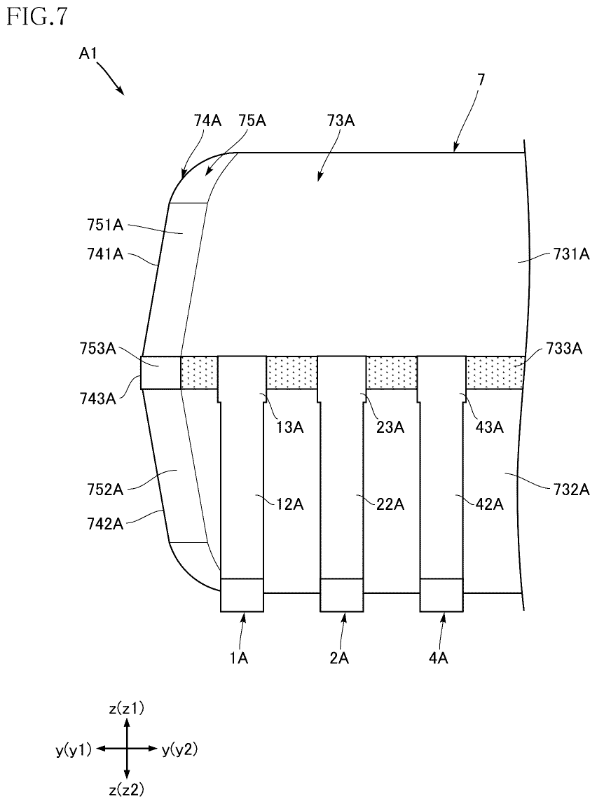

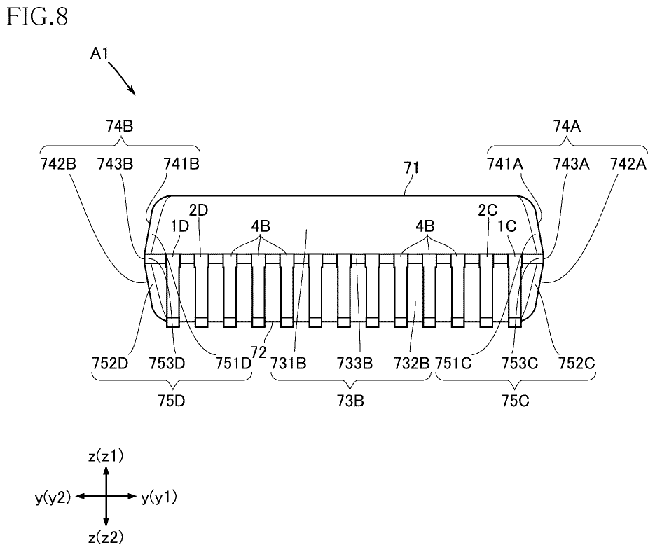

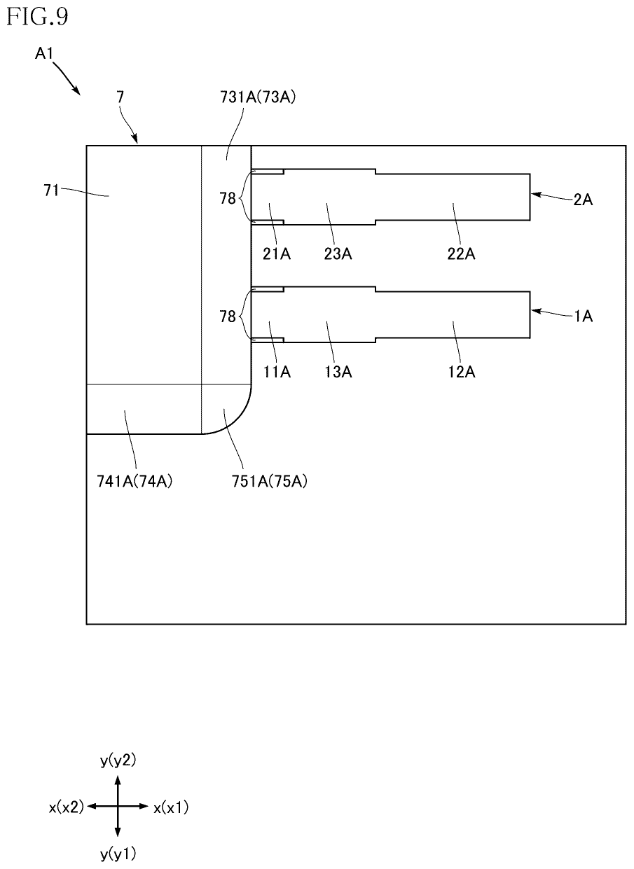

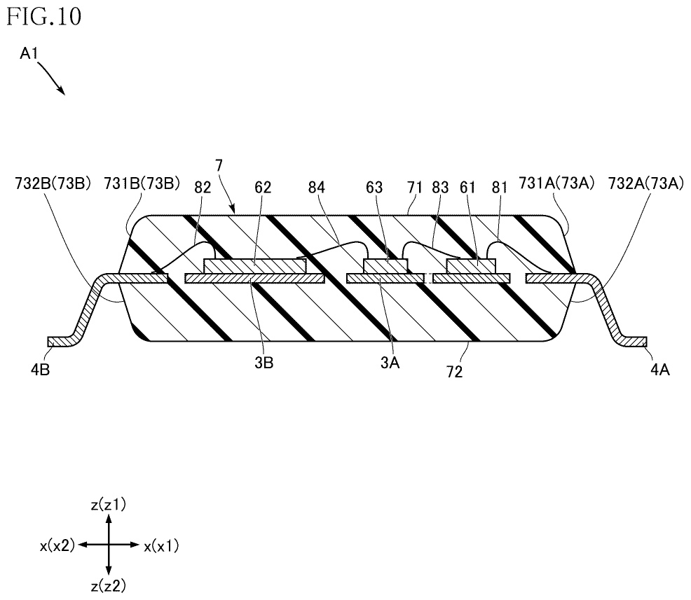

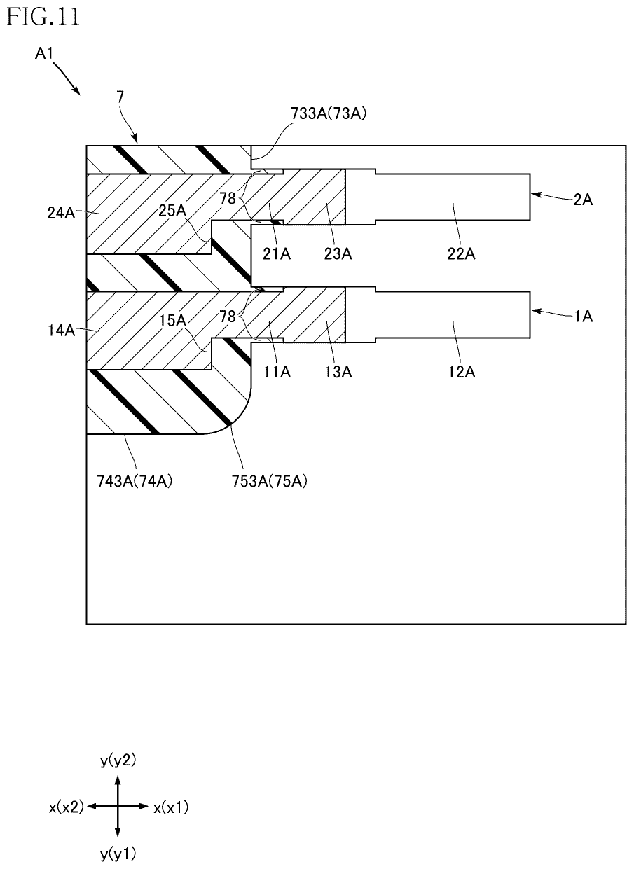

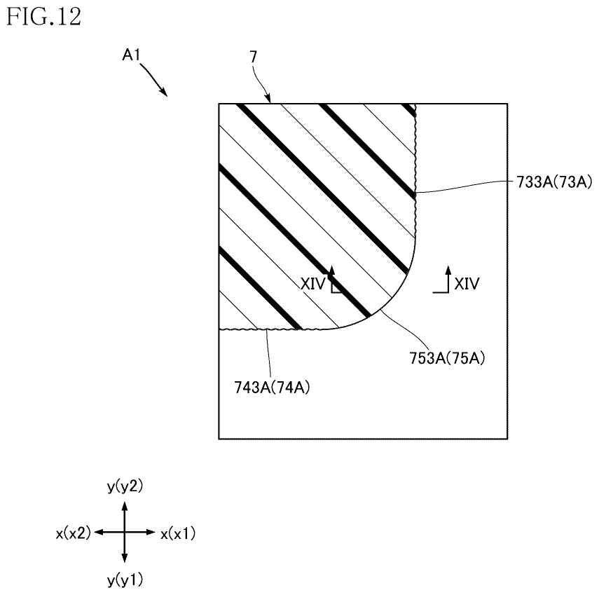

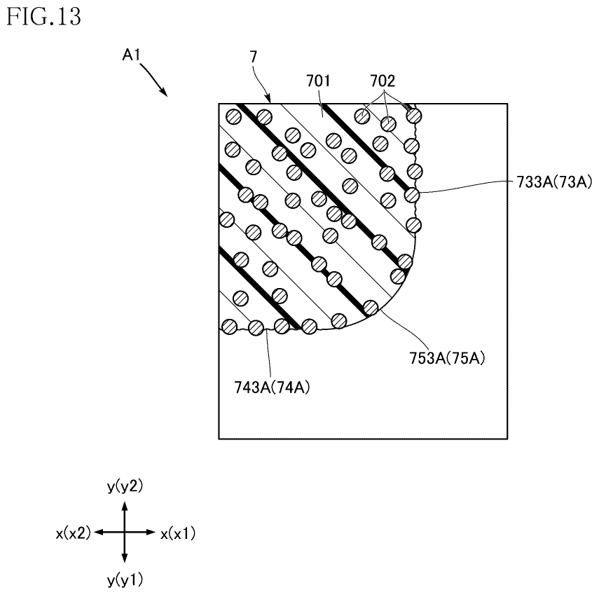

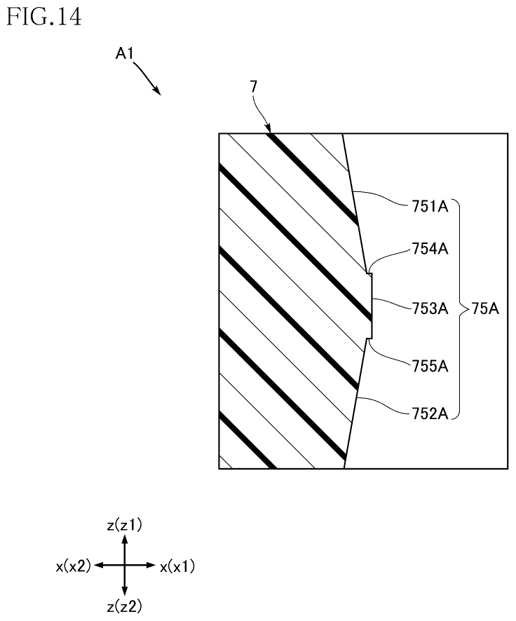

FIG. 1 is a plan view of the semiconductor device A1. FIG. 2 is a fragmentary plan view of the semiconductor device A1. FIG. 3 is a front view of the semiconductor device A1. FIG. 4 is a fragmentary enlarged front view of the semiconductor device A1. FIG. 5 is a rear view of the semiconductor device A1. FIG. 6 is a right-side view of the semiconductor device A1. FIG. 7 is a fragmentary enlarged right-side view of the semiconductor device A1. FIG. 8 is a left-side view of the semiconductor device A1. FIG. 9 is a fragmentary enlarged plan view of the semiconductor device A1. FIG. 10 is a sectional view taken along line X-X in FIG. 1. FIG. 11 is a fragmentary enlarged sectional view of the semiconductor device A1. FIG. 12 is a fragmentary enlarged sectional view of the semiconductor device A1. FIG. 13 is a fragmentary enlarged sectional view of the semiconductor device A1. FIG. 14 is a fragmentary enlarged sectional view taken along line XIV-XIV in FIG. 12.

The first direction z in these figures is defined as the first direction of the present disclosure. One side in the first direction z is referred to as the first side z1, and the other side as the second side z2. A direction perpendicular to the first direction z is defined as the second direction x. One side in the second direction x is referred to as the first side x1, and the other side as the second side x2. The direction perpendicular to the first direction z and the second direction x is defined as the third direction y. One side in the third direction y is referred to as the first side y1, and the other side as the second side y2.

The sealing resin 7 fully covers the one or more semiconductor elements 60 and the wires 81, 82, 83, and 84, and partly covers the first island 3A, the second island 3B, the first leads 1A, 1B, 1C, and 1D, and the second leads 2A, 2B, 2C, and 2D, and the leads 4A and 4B. The sealing resin 7 is electrically insulating and contains resin, for example. As shown in FIG. 13, the sealing resin 7 may be made of a base material 701 and a plurality of particles of a filler 702. In one example, the base material 701 may be an epoxy resin, and the filler 702 may be silica particles.

As shown in FIGS. 1 to 14, the sealing resin 7 has a resin first surface 71, a resin second surface 72, resin third surfaces 73A and 73B, resin fourth surfaces 74A and 74B, and resin fifth surfaces 75A, 75B, 75C, and 75D.

The resin first surface 71 faces toward the first side z1 in the first direction z. The resin first surface 71 may be flat. The resin second surface 72 faces toward the second side z2 in the first direction z. The resin second surface 72 may be flat.

The resin third surface 73A faces toward the first side x1 in the second direction x as viewed in the first direction z. The resin third surface 73A may be along the third direction y. The resin third surface 73A may include a resin fourth section 731A, a resin fifth section 732A, and a resin sixth section 733A.

The resin fourth section 731A is connected to the resin first surface 71. The resin fourth section 731A may be inclined with respect to the first direction z. The resin fifth section 732A is connected to the resin second surface 72. The resin fifth section 732A may be inclined with respect to the first direction z. The resin sixth section 733A is located between the resin fourth section 731A and the resin fifth section 732A. The resin sixth section 733A may be along the first direction z. The resin fifth section 732A may include a plurality of regions separated along the third direction y.

The resin third surface 73B faces toward the second side x2 in the second direction x as viewed in the first direction z. The resin third surface 73B may be along the third direction y. The resin third surface 73B may include a resin fourth section 731B, a resin fifth section 732B, and a resin sixth section 733B.

The resin fourth section 731B is connected to the resin first surface 71. The resin fourth section 731B may be inclined with respect to the first direction z. The resin fifth section 732B is connected to the resin second surface 72. The resin fifth section 732B may be inclined with respect to the first direction z. The resin sixth section 733B is located between the resin fourth section 731B and the resin fifth section 732B. The resin sixth section 733B may be along the first direction z. The resin fifth section 732B may include a plurality of regions separated along the third direction y.

The resin fourth surface 74A faces toward the first side y1 in the third direction y as viewed in the first direction z. The resin fourth surface 74A may be along the second direction x. The resin fourth surface 74A may include a resin seventh section 741A, a resin eighth section 742A, and a resin ninth section 743A.

The resin seventh section 741A is connected to the resin first surface 71. The resin seventh section 741A may be inclined with respect to the first direction z. The resin eighth section 742A is connected to the resin second surface 72. The resin eighth section 742A may be inclined with respect to the first direction z. The resin ninth section 743A is located between the resin seventh section 741A and the resin eighth section 742A. The resin ninth section 743A may be along the first direction z.

The resin fourth surface 74B faces toward the second side y2 in the third direction y as viewed in the first direction z. The resin fourth surface 74B may be along the second direction x. The resin fourth surface 74B may include a resin seventh section 741B, a resin eighth section 742B, and a resin ninth section 743B.

The resin seventh section 741B is connected to the resin first surface 71. The resin seventh section 741B may be inclined with respect to the first direction z. The resin eighth section 742B is connected to the resin second surface 72. The resin eighth section 742B may be inclined with respect to the first direction z. The resin ninth section 743B is located between the resin seventh section 741B and the resin eighth section 742B. The resin ninth section 743B may be along the first direction z.

The resin fifth surface 75A is located between the resin third surface 73A and the resin fourth surface 74A as viewed in the first direction z. The resin fifth surface 75A may include a resin first section 751A, a resin second section 752A, and a resin third section 753A.

The resin first section 751A is connected to the resin first surface 71. The resin second section 752B is connected to the resin second surface 72. The resin third section 753A is located between the resin first section 751A and the resin second section 752A. The resin first section 751A is located on the first side z1 in the first direction z with respect to the resin third section 753A. The resin second section 752A is located on the second side z2 in the first direction z with respect to the resin third section 753A.

The resin first section 751A and the resin second section 752A may be inclined relative to the second direction x, the third direction y, and the first direction z, and may be a convex surface, for example. The resin third section 753A may be along the first direction z and may be inclined relative to the second direction x and the third direction y. The shape of the resin third section 753A as viewed in the first direction z is not specifically limited and may be a convex surface, for example.

As shown in FIG. 14, the resin fifth surface 75A may additionally include a resin first intermediate section 754A and a resin second intermediate section 755A. The resin first intermediate section 754A is located between the resin first section 751A and the resin third section 753A and faces toward the first side z1 in the first direction z. The resin second intermediate section 755A is located between the resin second section 752A and the resin third section 753A and faces toward the second side z2 in the first direction z. The resin fifth surfaces 75B, 75C, and 75D may have a configuration similar to this.

As shown in FIG. 12, the surface roughness of the resin third section 753A is finer than the maximum surface roughness of the resin sixth section 733A and the maximum surface roughness of the resin ninth section 743A. These different surface roughnesses may result from the later-described method for manufacturing the semiconductor device A1. For example, the resin third section 753A may be a surface shaped by the inner surface of a mold, whereas the resin sixth section 733A and the resin ninth section 743A may be cut surfaces created by cutting an resin intermediate.

FIG. 13 shows the resin third section 753A, the resin sixth section 733A, and the resin ninth section 743A of an example in which the sealing resin 7 is made of a base material 701 and a plurality of particles of filler 702. The particles of filler 702 may be exposed to the outside to a greater extent at the resin sixth section 733A and the resin ninth section 743A than at the resin third section 753A. For example, the resin sixth section 733A and the resin ninth section 743A are created by cutting a resin intermediate containing the base material 701 and the particles of filler 702. As a result of cutting the base material 701, particles of filler 702 are exposed to the outside at the cut surface of the base material 701. In contrast, the resin sixth section 733A may be shaped by the inner surface of a mold. As a result, particles of filler 702 are typically not greatly exposed to the outside from the base material 701.

The resin fifth surface 75B is located between the resin third surface 73A and the resin fourth surface 74B as viewed in the first direction z. The resin fifth surface 75B may include a resin first section 751B, a resin second section 752B, and a resin third section 753B.

The resin first section 751B is connected to the resin first surface 71. The resin second section 752B is connected to the resin second surface 72. The resin third section 753B is located between the resin first section 751B and the resin second section 752B. The resin first section 751B is located on the first side z1 in the first direction z with respect to the resin third section 753B. The resin second section 752B is located on the second side z2 in the first direction z with respect to the resin third section 753B.

The resin first section 751B and the resin second section 752B may be inclined relative to the second direction x, the third direction y, and the first direction z, and may be a convex surface, for example. The resin third section 753B may be along the first direction z and may be inclined relative to the second direction x and the third direction y. The shape of the resin third section 753B as viewed in the first direction z is not specifically limited and may be a convex surface, for example.

Similarly to the resin third section 753A, the resin sixth section 733A, and the resin ninth section 743A shown in FIG. 12, the surface roughness of the resin third section 753B is finer than the maximum surface roughness of the resin sixth section 733A and the maximum surface roughness of the resin ninth section 743B. These different surface roughnesses may result from the later-described method for manufacturing the semiconductor device A1. For example, the resin third section 753B may be a surface shaped by the inner surface of a mold, whereas the resin sixth section 733A and the resin ninth section 743B may be cut surfaces created by cutting an resin intermediate.

The resin fifth surface 75C is located between the resin third surface 73B and the resin fourth surface 74A as viewed in the first direction z. The resin fifth surface 75C may include a resin first section 751C, a resin second section 752C, and a resin third section 753C.

The resin first section 751C is connected to the resin first surface 71. The resin second section 752C is connected to the resin second surface 72. The resin third section 753C is located between the resin first section 751C and the resin second section 752C. The resin first section 751C is located on the first side z1 in the first direction z with respect to the resin third section 753C. The resin second section 752C is located on the second side z2 in the first direction z with respect to the resin third section 753C.

The resin first section 751C and the resin second section 752C may be inclined relative to the second direction x, the third direction y, and the first direction z, and may be a convex surface, for example. The resin third section 753C may be along the first direction z and may be inclined relative to the second direction x and the third direction y. The shape of resin third section 753C as viewed in the first direction z is not specifically limited and may be a convex surface, for example.

Similarly to the resin third section 753A, the resin sixth section 733A, and the resin ninth section 743A shown in FIG. 12, the surface roughness of the resin third section 753C is finer than the maximum surface roughness of the resin sixth section 733B and the maximum surface roughness of the resin ninth section 743A. These different surface roughnesses may result from the later-described method for manufacturing the semiconductor device Al. For example, the resin third section 753C may be a surface shaped by the inner surface of a mold, whereas the resin sixth section 733B and the resin ninth section 743A may be cut surfaces created by cutting an resin intermediate.

The resin fifth surface 75D is located between the resin third surface 73B and the resin fourth surface 74B as viewed in the first direction z. The resin fifth surface 75D may include a resin first section 751D, a resin second section 752D, and a resin third section 753D.

The resin first section 751D is connected to the resin first surface 71. The resin second section 752D is connected to the resin second surface 72. The resin third section 753D is located between the resin first section 751D and the resin second section 752D. The resin first section 751D is located on the first side z1 in the first direction z with respect to the resin third section 753D. The resin second section 752D is located on the second side z2 in the first direction z with respect to the resin third section 753D.

The resin first section 751D and the resin second section 752D may be inclined relative to the second direction x, the third direction y, and the first direction z, and may be a convex surface,, for example. The resin third section 753D may be along the first direction z and may be inclined relative to the second direction x and the third direction y. The shape of the resin third section 753D as viewed in the first direction z is not specifically limited and may be a convex surface, for example.

Similarly to the resin third section 753A, the resin sixth section 733A, and the resin ninth section 743A shown in FIG. 12, the surface roughness of the resin third section 753D is finer than the maximum surface roughness of the resin sixth section 733B and the maximum surface roughness of the resin ninth section 743B. These different surface roughnesses may result from the later-described method for manufacturing the semiconductor device A1. For example, the resin third section 753D may be a surface shaped by the inner surface of a mold, whereas the resin sixth section 733B and the resin ninth section 743B may be cut surfaces created by cutting an resin intermediate.

The sealing resin 7 may additionally include a plurality of coating portions 78. The coating portions 78 are provided on the opposite surfaces in the third direction y of each of first root portions 11A to 11D. second root portions 21A to 21D, and root portions 41A and 41B. The coating portions 78 may be flush with the opposite surfaces in the third direction y of first widened portions 13A to 13D, second widened portions 23A to 23D, and widened portions 43A and 43B.

The first lead 1A may be electrically connected to the one or more semiconductor elements 60, for example. The first lead 1A may be made of a metal, such as copper (Cu), nickel (Ni), iron (Fe), or an alloy of any of these metals. The first lead 1A may have a thickness of 100 μm or more and 500 μm or less, for example. The first lead 1A may protrude from the resin sixth section 733A in the second direction x toward the first side x1. The thickness of the first lead 1A in the first direction z may be the same as the dimension of the resin sixth section 733A in the first direction z.

The first lead 1A is located on the second side y2 in the third direction y with respect to the resin third section 753A. A portion of the resin sixth section 733A is located between the first lead 1A and the resin third section 753A.

The first lead 1A may include a first root portion 11A, a first end portion 12A, a first widened portion 13A, a first connecting portion 14A, and a first stepped portion 15A. The first root portion 11A, the first end portion 12A, and the first widened portion 13A may extend in the second direction x as viewed in the first direction z. The first root portion 11A, the first end portion 12A, and the first widened portion 13A may have a bent configuration as viewed in the third direction y.

The first root portion 11A is a portion joined to the resin sixth section 733A. The first root portion 11A may have a dimension of 100 μm or more and 500 μm or less, for example, in the second direction x. The first end portion 12A is the extremity in the second direction x. The first widened portion 13A is located between the first root portion 11A and the first end portion 12A. The first widened portion 13A may be greater in dimension in the third direction y than the first root portion 11A and the first end portion 12A. For example, the first widened portion 13A may have edges each located from 0 to 100 μm further in the third direction y from the edges of the first root portion 11A and the first end portion 12A.

The first connecting portion 14A is covered with the sealing resin 7. The first stepped portion 15A is a portion of the first connecting portion 14A that has a stepped profile. The first connecting portion 14A may have a through-hole 141A. The through-hole 141A penetrates the first connecting portion 14A in the first direction z.

The first lead 1B may be electrically connected to the one or more semiconductor elements 60, for example. The first lead 1B may be made of a metal, such as copper (Cu), nickel (Ni), iron (Fe), or an alloy of any of these metals. The first lead 1B may have a thickness of 100 μm or greater and 500 μm or less, for example. The first lead 1B may protrude from the resin sixth section 733A in the second direction x toward the first side x1. The thickness of the first lead 1B in the first direction z may be the same as the dimension of the resin sixth section 733A in the first direction z.

The first lead 1B is located on the first side y1 in the third direction y with respect to the resin third section 753B. A portion of the resin sixth section 733A is located between the first lead 1B and the resin third section 753B.

The first lead 1B may include a first root portion 11B, a first end portion 12B, a first widened portion 13B, a first connecting portion 14B, and a first stepped portion 15B. The first root portion 11B, the first end portion 12B, and the first widened portion 13B may extend in the second direction x as viewed in the first direction z. The first root portion 11B, the first end portion 12B, and the first widened portion 13B may have a bent configuration as viewed in the third direction y.

The first root portion 11B is a portion joined to the resin sixth section 733A. The first root portion 11B may have a dimension of 100 μm or more and 500 μm or less, for example, in the second direction x. The first end portion 12B is the extremity in the second direction x. The first widened portion 13B is located between the first root portion 11B and the first end portion 12B. The first widened portion 13B may be greater in dimension in the third direction y than the first root portion 11B and the first end portion 12B. For example, the first widened portion 13B may have edges each located from 0 to 100 μm further in the third direction y from the edges of the first root portion 11B and the first end portion 12B.

The first connecting portion 14B is covered with the sealing resin 7. The first stepped portion 15B is a portion of the first connecting portion 14B that has a stepped profile. The first connecting portion 14B may have a through-hole 141B. The through-hole 141B penetrates the first connecting portion 14B in the first direction z.

The first lead 1C may be electrically connected to the one or more semiconductor elements 60, for example. The first lead 1C may be made of a metal, such as copper (Cu), nickel (Ni), iron (Fe), or an alloy of any of these metals. The first lead 1C may have a thickness of 100 μm or greater and 500 μm or less, for example. The first lead 1C may protrude from the resin sixth section 733B in the second direction x toward the second side x2. The thickness of the first lead 1C in the first direction z may be the same as the dimension of the resin sixth section 733B in the first direction z.

The first lead 1C is located on the second side y2 in the third direction y with respect to the resin third section 753C. A portion of the resin sixth section 733B is located between the first lead 1C and the resin third section 753C.

The first lead 1C may include a first root portion 11C, a first end portion 12C, a first widened portion 13C, a first connecting portion 14C, and a first stepped portion 15C. The first root portion 11C, the first end portion 12C, and the first widened portion 13C may extend in the second direction x as viewed in the first direction z. The first root portion 11C, the first end portion 12C, and the first widened portion 13C may have a bent configuration as viewed in the third direction y.

The first root portion 11C is a portion joined to the resin sixth section 733B. The first root portion 11C may have a dimension of 100 μm or more and 500 μm or less, for example, in the second direction x. The first end portion 12C is the extremity in the second direction x. The first widened portion 13C is located between the first root portion 11C and the first end portion 12C. The first widened portion 13C may be greater in dimension in the third direction y than the first root portion 11C and the first end portion 12C. For example, the first widened portion 13C may have edges each located from 0 to 100 μm further in the third direction y from the edges of the first root portion 11C and the first end portion 12C.

The first connecting portion 14C is covered with the sealing resin 7. The first stepped portion 15C is a portion of the first connecting portion 14C that has a stepped profile. The first connecting portion 14C may have a through-hole 141C. The through-hole 141C penetrates the first connecting portion 14C in the first direction z.

The first lead 1D may be electrically connected to the one or more semiconductor elements 60, for example. The first lead 1D may be made of a metal, such as copper (Cu), nickel (Ni), iron (Fe), or an alloy of any of these metals. The first lead 1D may have a thickness of 100 μm or greater and 500 μm or less, for example. The first lead 1D may protrude from the resin sixth section 733B in the second direction x toward the second side x2. The thickness of the first lead 1D in the first direction z may be the same as the dimension of the resin sixth section 733B in the first direction z.

The first lead 1D is located on the first side y1 in the third direction y with respect to the resin third section 753D. A portion of the resin sixth section 733B is located between the first lead 1D and the resin third section 753D.

The first lead 1D may include a first root portion 11D, a first end portion 12D, a first widened portion 13D, a first connecting portion 14D, and a first stepped portion 15D. The first root portion 11D, the first end portion 12D, and the first widened portion 13D may extend in the second direction x as viewed in the first direction z. The first root portion 11D, the first end portion 12D, and the first widened portion 13D may have a bent configuration as viewed in the third direction y.

The first root portion 11D is a portion joined to the resin sixth section 733B. The first root portion 11D may have a dimension of 100 μm or more and 500 μm or less, for example, in the second direction x. The first end portion 12D is the extremity in the second direction x. The first widened portion 13D is located between the first root portion 11D and the first end portion 12D. The first widened portion 13D may be greater in dimension in the third direction y than the first root portion 11D and the first end portion 12D. For example, the first widened portion 13D may have edges each located from 0 to 100 μm further in the third direction y from the edges of the first root portion 11D and the first end portion 12D.

The first connecting portion 14D is covered with the sealing resin 7. The first stepped portion 15D is a portion of the first connecting portion 14D that has a stepped profile. The first connecting portion 14D may have a through-hole 141D. The through-hole 141D penetrates the first connecting portion 14D in the first direction z.

The second lead 2A may be electrically connected to the one or more semiconductor elements 60, for example. The second lead 2A may be made a metal, such as copper (Cu), nickel (Ni), iron (Fe), or an alloy of any of these metals. The second lead 2A may have a thickness of 100 μm or more and 500 μm or less, for example. The second lead 2A may protrude from the resin sixth section 733A in the second direction x toward the first side x1. The thickness of the second lead 2A in the first direction z may be the same as the dimension of the resin sixth section 733A in the first direction z.

The second lead 2A is located on the second side y2 in the third direction y with respect to the first lead 1A. A portion of the resin sixth section 733A is located between the second lead 2A and the first lead 1A.

The second lead 2A may include a second root portion 21A, a second end portion 22A, a second widened portion 23A, a second connecting portion 24A, a second stepped portion 25A, and a second pad portion 26A. The second root portion 21A, the second end portion 22A, and the second widened portion 23A may extend in the second direction x as viewed in the first direction z. The second root portion 21A, the second end portion 22A, and the second widened portion 23A may have a bent configuration as viewed in the third direction y.

The second root portion 21A is a portion joined to the resin sixth section 733A. The second root portion 21A may have a dimension of 100 μm or more and 500 μm or less, for example, in the second direction x. The second end portion 22A is the extremity in the second direction x. The second widened portion 23A is located between the second root portion 21A and the second end portion 22A. The second widened portion 23A may be greater in dimension in the third direction y than the second root portion 21A and the second end portion 22A. For example, the second widened portion 23A may have edges each located from 0 to 100 μm further in the third direction y from the edges of the second root portion 21A and the second end portion 22A.

The second connecting portion 24A is covered with the sealing resin 7. The second stepped portion 25A is a portion of the second connecting portion 24A that has a stepped profile. The second pad portion 26A is connected to the end of the second connecting portion 24A on the second side x2 in the second direction x.

The second lead 2B may be electrically connected to the one or more semiconductor elements 60, for example. The second lead 2B may be made of a metal, such as copper (Cu), nickel (Ni), iron (Fe), or an alloy of any of these metals. The second lead 2B may have a thickness of 100 μm or greater and 500 μm or less, for example. The second lead 2B may protrude from the resin sixth section 733A in the second direction x toward the first side x1. The thickness of the second lead 2B in the first direction z may be the same as the dimension of the resin sixth section 733A in the first direction z.

The second lead 2B is located on the first side y1 in the third direction y with respect to the first lead 1B. A portion of the resin sixth section 733A is located between the second lead 2B and the first lead 1B.

The second lead 2B may include a second root portion 21B, a second end portion 22B, a second widened portion 23B, a second connecting portion 24B, a second stepped portion 25B, and a second pad portion 26B. The second root portion 21B, the second end portion 22B, and the second widened portion 23B may extend in the second direction x as viewed in the first direction z. The second root portion 21B, the second end portion 22B, and the second widened portion 23B may have a bent configuration as viewed in the third direction y.

The second root portion 21B is a portion joined to the resin sixth section 733A. The second root portion 21B may have a dimension of 100 μm or more and 500 μm or less, for example, in the second direction x. The second end portion 22B is the extremity in the second direction x. The second widened portion 23B is located between the second root portion 21B and the second end portion 22B. The second widened portion 23B may be greater in dimension in the third direction y than the second root portion 21B and the second end portion 22B. For example, the second widened portion 23B may have edges each located from 0 to 100 μm further in the third direction y from the edges of the second root portion 21B and the second end portion 22B.

The second connecting portion 24B is covered with the sealing resin 7. The second stepped portion 25B is a portion of the second connecting portion 24B that has a stepped profile. The second pad portion 26B is connected to the end of the second connecting portion 24B on the second side x2 in the second direction x.

The second lead 2C may be electrically connected to the one or more semiconductor elements 60, for example. The second lead 2C may be made of a metal, such as copper (Cu), nickel (Ni), iron (Fe), or an alloy of any of these metals. The second lead 2C may have a thickness of 100 μm or greater and 500 μm or less, for example. The second lead 2C may protrude from the resin sixth section 733B in the second direction x toward the second side x2. The thickness of the second lead 2C in the first direction z may be the same as the dimension of the resin sixth section 733B in the first direction z.

The second lead 2C is located on the second side y2 in the third direction y with respect to the first lead 1C. A portion of the resin sixth section 733B is located between the second lead 2C and the first lead 1C.

The second lead 2C may include a second root portion 21C, a second end portion 22C, a second widened portion 23C, a second connecting portion 24C, a second stepped portion 25C, and a second pad portion 26C. The second root portion 21C, the second end portion 22C, and the second widened portion 23C may extend in the second direction x as viewed in the first direction z. The second root portion 21C, the second end portion 22C, and the second widened portion 23C may have a bent configuration as viewed in the third direction y.

The second root portion 21C is a portion joined to the resin sixth section 733B. The second root portion 21C may have a dimension of 100 μm or more and 500 μm or less, for example, in the second direction x. The second end portion 22C is the extremity in the second direction x. The second widened portion 23C is located between the second root portion 21C and the second end portion 22C. The second widened portion 23C may be greater in dimension in the third direction y than the second root portion 21C and the second end portion 22C. For example, the second widened portion 23C may have edges each located from 0 to 100 μm further in the third direction y from the edges of the second root portion 21C and the second end portion 22C.

The second connecting portion 24C is covered with the sealing resin 7. The second stepped portion 25C is a portion of the second connecting portion 24C that has a stepped profile. The second pad portion 26C is connected to the end of the second connecting portion 24C on the first side x1 in the second direction x.

The second lead 2D may be electrically connected to the one or more semiconductor elements 60, for example. The second lead 2D may be made of a metal, such as copper (Cu), nickel (Ni), iron (Fe), or an alloy of any of these metals. The second lead 2D may have a thickness of 100 μm or greater and 500 μm or less, for example. The second lead 2D may protrude from the resin sixth section 733B in the second direction x toward the second side x2. The thickness of the second lead 2D in the first direction z may be the same as the dimension of the resin sixth section 733B in the first direction z.

The second lead 2D is located on the first side y1 in the third direction y with respect to the first lead 1D. A portion of the resin sixth section 733B is located between the second lead 2D and the first lead 1D.

The second lead 2D may include a second root portion 21D, a second end portion 22D, a second widened portion 23D, a second connecting portion 24D, a second stepped portion 25D, and a second pad portion 26D. The second root portion 21D, the second end portion 22D, and the second widened portion 23D may extend in the second direction x as viewed in the first direction z. The second root portion 21D, the second end portion 22D, and the second widened portion 23D may have a bent configuration as viewed in the third direction y.

The second root portion 21D is a portion joined to the resin sixth section 733B. The second root portion 21D may have a dimension of 100 μm or more and 500 μm or less, for example, in the second direction x. The second end portion 22D is the extremity in the second direction x.

The second widened portion 23D is located between the second root portion 21D and the second end portion 22D. The second widened portion 23D may be greater in dimension in the third direction y than the second root portion 21D and the second end portion 22D. For example, the second widened portion 23D may have edges each located from 0 to 100 μm further in the third direction y from the edges of the second root portion 21D and the second end portion 22D.

The second connecting portion 24D is covered with the sealing resin 7. The second stepped portion 25D is a portion of the first connecting portion 14D that has a stepped profile. The second pad portion 26D is connected to the end of the second lead 2D on the first side x1 in the second direction x.

The first island 3A may be where one or more semiconductor elements 60 are mounted, for example. The shape of the first island 3A is not specifically limited, and examples include a rectangular shape. The first island 3A is covered with the sealing resin 7. The first island 3A may be made a metal, such as copper (Cu), nickel (Ni), iron (Fe), or an alloy of any of these metals. The first island 3A may have a thickness of 100 μm or more and 500 μm or less, for example.

The first island 3A is connected to each of the second connecting portions 24A and 24B. The first island 3A may be integral with the first leads 1A and 1B. The second connecting portions 24A and 24B are connected to the opposite ends of the first island 3A in the third direction y.

The first island 3A may have a plurality of through-holes 31A. The through-holes 31A penetrate the first island 3A in the first direction z. The through-holes 31A may be aligned in the third direction y.

The second island 3B is where one or more semiconductor elements 60 are mounted, for example. The shape of the second island 3B is not specifically limited, and examples include a rectangular shape. The second island 3B may be located on the second side x2 in the second direction x with respect to the first island 3A. The second island 3B is covered with the sealing resin 7. The second island 3B may be made a metal, such as copper (Cu), nickel (Ni), iron (Fe), or an alloy of any of these metals. The second island 3B may have a thickness of 100 μm or more and 500 μm or less, for example.

The second island 3B is connected to each of the first connecting portions 14C and 14D. The second island 3B may be integral with the first leads 1C and 1D. The first connecting portions 14C and 14D are connected to the opposite ends of the second island 3B in the third direction y.

The plurality of leads 4A may be electrically connected to one or more semiconductor elements 60, for example. The leads 4A may be made a metal, such as copper (Cu), nickel (Ni), iron (Fe), or an alloy of any of these metals. The leads 4A may have a thickness of 100 μm or greater and 500 μm or less, for example. The leads 4A may protrude from the resin sixth section 733A in the second direction x toward the first side x1. The thickness of the leads 4A in the first direction z may be the same as the dimension of the resin sixth section 733A in the first direction z.

The leads 4A may be arranged side by side in the third direction y. The leads 4A may be located between the second leads 2A and 2B in the third direction y. A portion of the resin sixth section 733A is located between each two adjacent leads 4A. A portion of the resin sixth section 733A is also located between the leads 4A and the second lead 2A. A portion of the resin sixth section 733A is also located between the leads 4A and the second lead 2B.

Each lead 4A may include a root portion 41A, an end portion 42A, a widened portion 43A, a connecting portion 44A, a stepped portion 45A, and a pad portion 46A. The root portion 41A, the end portion 42A, and the widened portion 43A may extend in the second direction x as viewed in the first direction z. The root portion 41A, the end portion 42A, and the widened portion 43A may have a bent configuration as viewed in the third direction y.

The root portion 41A is a portion joined to the resin sixth section 733A. The root portion 41A may have a dimension of 100 μm or more and 500 μm or less, for example, in the second direction x. The end portion 42A is the extremity in the second direction x. The widened portion 43A is located between the root portion 41A and the end portion 42A. The widened portion 43A may be greater in dimension in the third direction y than the root portion 41A and the end portion 42A. For example, the widened portion 43A may have edges each located from 0 to 100 μm further in the third direction y from the edges of the root portion 41A and the end portion 42A.

The connecting portion 44A is covered with the sealing resin 7. The stepped portion 45A is a portion of the connecting portion 44A that has a stepped profile. The pad portion 46A is connected to the end of the connecting portion 44A on the second side x2 in the second direction X.

The plurality of leads 4B may be electrically connected to one or more semiconductor elements 60, for example. The leads 4B may be made a metal, such as copper (Cu), nickel (Ni), iron (Fe), or an alloy of any of these metals. The leads 4B may have a thickness of 100 μm or greater and 500 μm or less, for example. The leads 4B may protrude from the resin sixth section 733B in the second direction x toward the second side x2. The thickness of the leads 4B in the first direction z may be the same as the dimension of the resin sixth section 733B in the first direction z.

The leads 4B may be arranged side by side in the third direction y. The leads 4B may be located between the second leads 2C and 2D in the third direction y. A portion of the resin sixth section 733B is located between each two adjacent leads 4B. A portion of the resin sixth section 733B is also located between the leads 4B and the second lead 2C. A portion of the resin sixth section 733B is also located between the leads 4B and the second lead 2D.

Each lead 4B may include a root portion 41B, an end portion 42B, a widened portion 43B, a connecting portion 44B, a stepped portion 45B, and a pad portion 46B. The root portion 41B, the end portion 42B, and the widened portion 43B may extend in the second direction x as viewed in the first direction z. The root portion 41B, the end portion 42B, and the widened portion 43B may have a bent configuration as viewed in the third direction y.

The root portion 41B is a portion joined to the resin sixth section 733B. The root portion 41B may have a dimension of 100 μm or more and 500 μm or less, for example, in the second direction x. The end portion 42B is the extremity in the second direction x. The widened portion 43B is located between the root portion 41B and the end portion 42B. The widened portion 43B may be greater in dimension in the third direction y than the root portion 41B and the end portion 42B. For example, the widened portion 43B may have edges each located from 0 to 100 μm further in the third direction y from the edges of the root portion 41B and the end portion 42B.

The connecting portion 44B is covered with the sealing resin 7. The stepped portion 45B is a portion of the connecting portion 44B that has a stepped profile. The pad portion 46B is connected to the end of the connecting portion 44B on the first side x1 in the second direction x.

The one or more semiconductor elements 60 are central to the functionality of the semiconductor device A1. As shown in FIG. 2, the one or more semiconductor elements 60 may include a first semiconductor element 61, a second semiconductor element 62, and an insulating element 63. In the semiconductor device A1, the first semiconductor element 61, the second semiconductor element 62, and the insulating element 63 are each composed of a single element. As viewed in the first direction z, the first semiconductor element 61, the second semiconductor element 62. and the insulating element 63 are each rectangular that is longer in the third direction y.

The first semiconductor element 61 is a controller (a control element) for a gate driver that drives a switching element, such as an insulated gate bipolar transistor (IGBT) or a metal-oxide-semiconductor field effect transistor (MOSFET). The first semiconductor element 61 includes a circuit for converting a control signal received from an ECU or the like into a pulse width modulation (PWM) control signal, a transmitting circuit for transmitting the PWM control signal to the second semiconductor element 62, and a receiving circuit for receiving an electrical signal from the second semiconductor element 62.

The second semiconductor element 62 is a gate driver (a drive element) for driving a switching element. The second semiconductor element 62 includes a receiving circuit for receiving a PWM control signal, a circuit for driving a switching element according to the PWM control signal, and a transmitting circuit for transmitting an electrical signal to the first semiconductor element 61. Examples of electrical signals include an output signal of a temperature sensor disposed near a motor.

The insulating element 63 transmits a PWM control signal and other electrical signals in an isolated state. In the semiconductor device A1, the insulating element 63 is of an inductive-coupling type. Examples of the inductive-coupling insulating element 63 include an insulating transformer. An insulating transformer enables transmission of electrical signals through the inductive coupling between two inductors (coils). The insulating element 63 includes a substrate made of silicon and inductors made of copper on the substrate. The inductors includes a transmitting-side inductor and a receiving-side inductor that are stacked together in the first direction z. A layer of dielectric material, such as silicon dioxide (SiO₂), is interposed between the transmitting-side inductor and the receiving-side inductor. The dielectric layer electrically insulates the transmitting-side inductor and the receiving-side inductor from each other. Alternatively, the insulating element 63 may be of a capacitive type. Examples of the capacitive insulating element 63 include a capacitor. Alternatively, the insulating element 63 may be a photocoupler.

In the semiconductor device A1, the second semiconductor element 62 requires a higher power supply voltage than the first semiconductor element 61. Thus, a large potential difference will be generated between the first semiconductor element 61 and the second semiconductor element 62. To address this, the semiconductor device Al includes the insulating element 63 to provide electrical isolation between a first circuit that includes the first semiconductor element 61 and a second circuit that includes the second semiconductor element 62. The first circuit and the second circuit will have mutually different potentials. In the semiconductor device A1, the potential of the second circuit is higher than the potential of the first circuit. With this being the situation, the insulating element 63 transfers signals between the first circuit and the second circuit. In an inverter device for an electric vehicle or a hybrid vehicle, the voltage applied to the ground of the first semiconductor element 61 is 0 V or so, whereas the voltage applied to the ground of the second semiconductor element 62 may transiently exceed 600 V.

As shown in FIG. 2, the first semiconductor element 61 is provided with a plurality of electrodes 611. The electrodes 611 are electrically connected to a circuit formed in the first semiconductor element 61. Similarly, the second semiconductor element 62 is provided with a plurality of electrodes 621. The electrodes 621 are electrically connected to a circuit formed in the second semiconductor element 62.

As shown in FIG. 2, the insulating element 63 is located between the first semiconductor element 61 and the second semiconductor element 62 in the third direction y. The insulating element 63 is provided with a plurality of first electrodes 631 and a plurality of second electrodes 632. Each of the first electrodes 631 and the second electrodes 632 is electrically connected to either the transmitting-side inductor or the receiving-side inductor. The first electrodes 631 are aligned in the third direction y at positions offset toward the first side x1 in the second direction x.

The second electrodes 632 are aligned in the third direction y at positions offset toward the second side x2 in the second direction x.

The first semiconductor element 61 and the insulating element 63 may be mounted on the first island 3A. The second semiconductor element 62 may be mounted on the second island 3B.

The electrodes 611 may include those electrically connected to the first connecting portions 14A and 14B, the second pad portion 26B, and the pad portions 46A each via a wire 81. The electrodes 611 may additionally include those electrically connected to the first electrodes 631 each via a wire 83.

The electrodes 621 may include those electrically connected to the first connecting portions 14C and 14D, the second pad portions 26C and 26D, and the pad portions 46B each via a wire 82. The electrodes 621 may additionally include those electrically connected to the second electrodes 632 each via a wire 84.

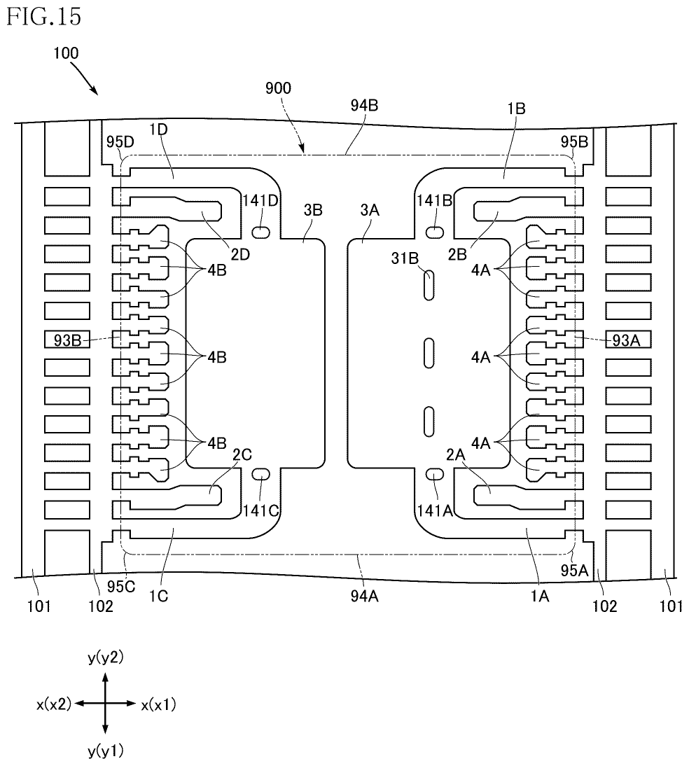

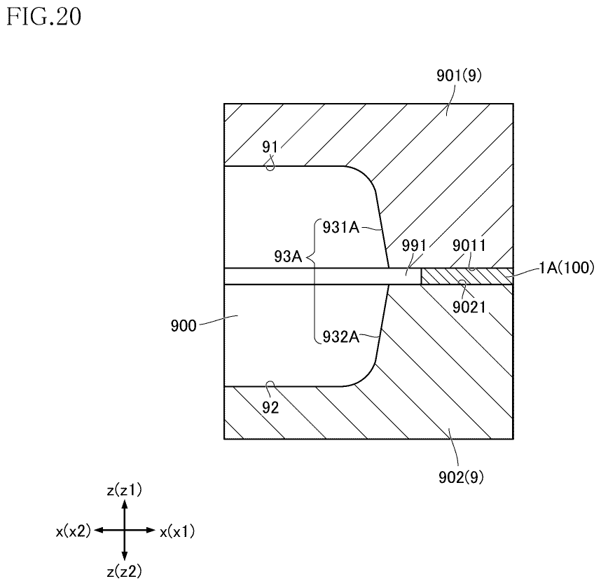

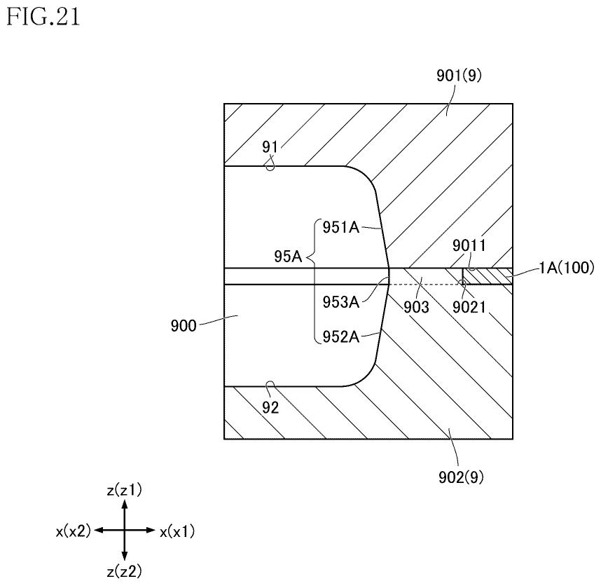

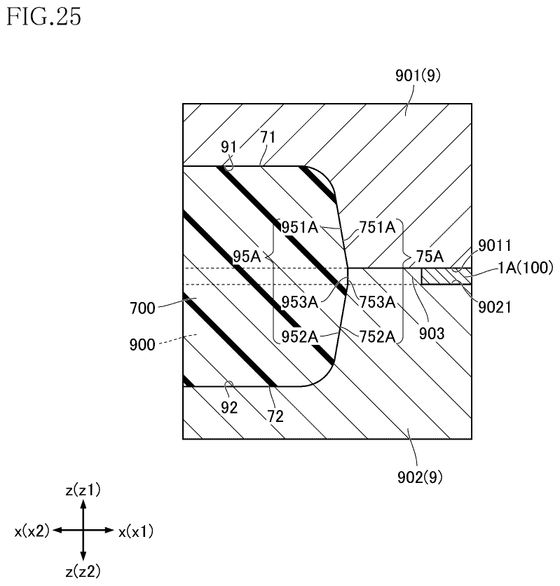

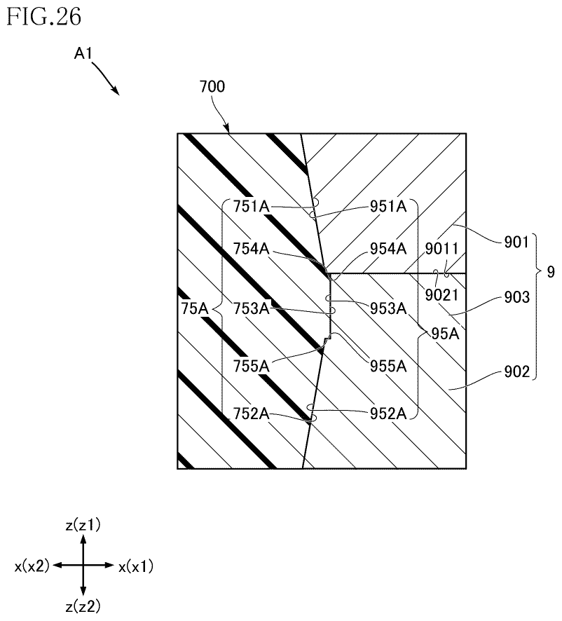

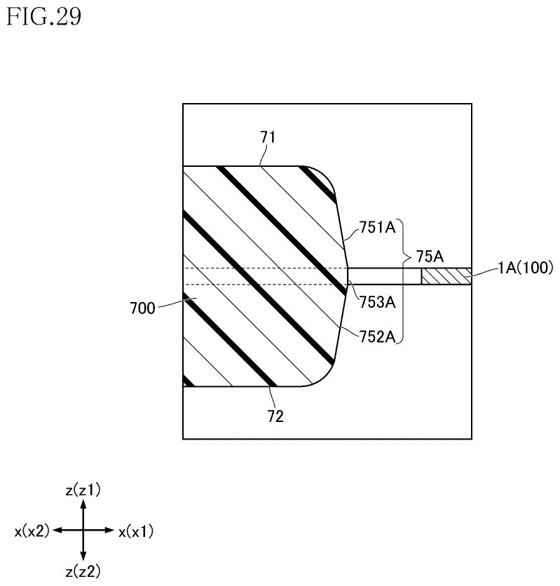

The following describes a method for manufacturing a semiconductor device A1, with reference to FIGS. 15 to 30.

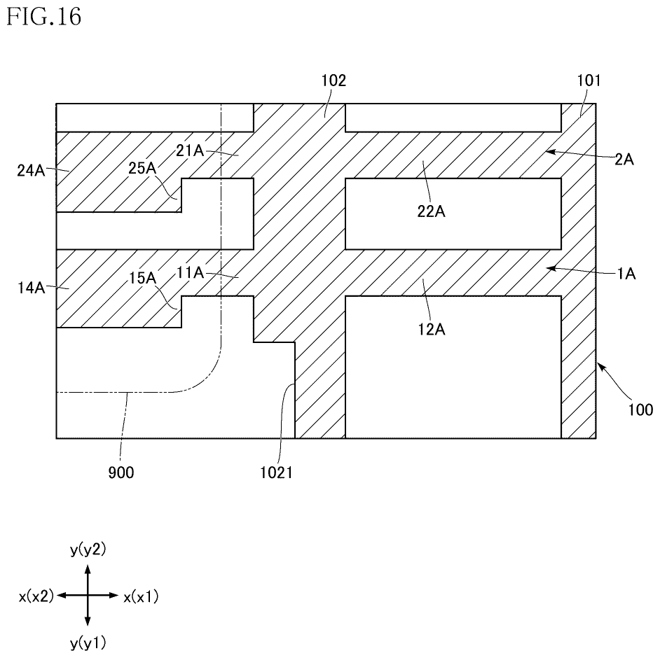

The method includes preparing a lead frame 100 shown in FIGS. 15 and 16. The lead frame 100 is made of a metal, such as copper (Cu), nickel (Ni), iron (Fe), or an alloy of any of these metals. The lead frame 100 may include first leads 1A to 1D, second leads 2A to 2D, a first island 3A, a second island 3B, a plurality of leads 4A and 4B, a plurality of frame portions 101, and a plurality of bar portions 102. The frame portions 101 and the bar portions 102 connecting together the first leads 1A to 1D, the second leads 2A to 2D, and the leads 4A and 4B.

As shown in FIG. 16, each bar portion 102 has a plurality of recessed portions 1021. The recessed portion 1021 shown in FIG. 16 is recessed in the second direction x toward the first side x1 (outside).

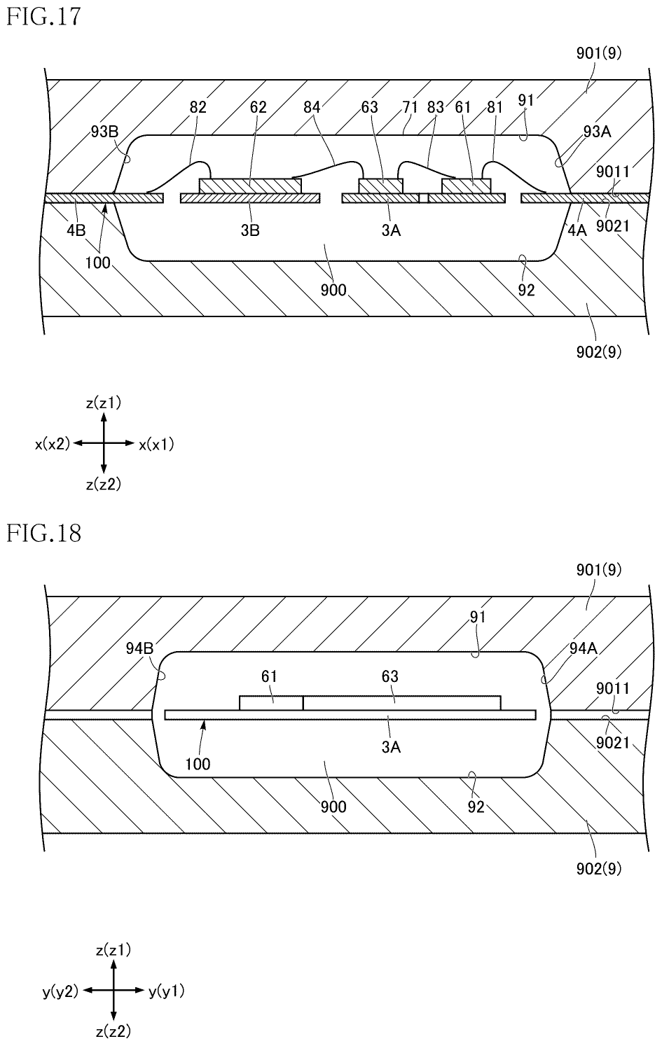

Subsequently, the method includes mounting the first semiconductor element 61, the second semiconductor element 62, and the insulating element 63 on the lead frame 100 as shown in FIGS. 17 and 18. Subsequently, the wires 81, 82, 83, and 84 are bonded.

Subsequently, a mold 9 is set as shown in FIGS. 17 to 22. The mold 9 has a cavity 900. The mold 9 is placed to ensure that the cavity 900 encloses the first semiconductor element 61, the second semiconductor element 62, the insulating element 63, the first island 3A, the second island 3B, and other necessary portions.

The configuration of the mold 9 is not specifically limited. In the illustrated example, the mold 9 includes a first mold 901 and a second mold 902. The first mold 901 is placed on the first side z1 in the first direction z with respect to the lead frame 100. The second mold 902 is placed on the second side z2 in the first direction z with respect to the lead frame 100.

The first mold 901 may have a first mold opposing surface 9011. The first mold opposing surface 9011 is a flat surface facing the second side z2 in the first direction z and surrounds the cavity 900 on all four sides as viewed in the first direction z. The first mold opposing surface 9011 is pressed against the lead frame 100 from the first side z1 in the first direction z.

The second mold 902 may have a second mold opposing surface 9021. The second mold opposing surface 9021 is a flat surface facing the first side z1 in the first direction z and surrounds the cavity 900 on all four sides as viewed in the first direction z. The second mold opposing surface 9021 may be placed face to face with the first mold opposing surface 9011 in the first direction z. The second mold opposing surface 9021 is pressed against the lead frame 100 from the second side z2 in the first direction z.

The mold 9 may have a mold first surface 91, a mold second surface 92, mold third surfaces 93A and 93B, mold fourth surfaces 94A and 94B, and mold fifth surfaces 95A, 95B, 95C, and 95D. The mold first surface 91, the mold second surface 92, the mold third surfaces 93A and 93B, the mold fourth surfaces 94A and 94B, and the mold fifth surfaces 95A, 95B, 95C, and 95D are for forming the resin first surface 71, the resin second surface 72, the resin third surfaces 73A and 73B, the resin fourth surfaces 74A and 74B, and the resin fifth surfaces 75A, 75B, 75C, and 75D, respectively.

The mold first surface 91 is located on the first side z1 in the first direction z, facing toward the second side z2. The mold second surface 92 is located on the second side z2 in the first direction z, facing toward the first side z1. The mold third surface 93A faces toward the second side x2 in the second direction x as viewed in the first direction z. The mold third surface 93B faces toward the first side x1 in the second direction x as viewed in the first direction z. The mold fourth surface 94A faces toward the second side y2 in the third direction y as viewed in the first direction z. The mold fourth surface 94B faces toward the first side y1 in the third direction y as viewed in the first direction z.

The mold third surfaces 93A and 93B and the mold fourth surfaces 94A and 94B may each include a portion corresponding to one of the resin fourth sections 731A and 731B and the resin seventh sections 741A and 741B. These portions are located on the first side z1 in the first direction z with respect to the lead frame 100.

The mold third surfaces 93A and 93B and the mold fourth surfaces 94A and 94B may each include a portion corresponding to one of the resin fifth sections 732A and 732B and the resin eighth sections 742A and 742B. These portions are located on the second side z2 in the first direction z with respect to the lead frame 100.

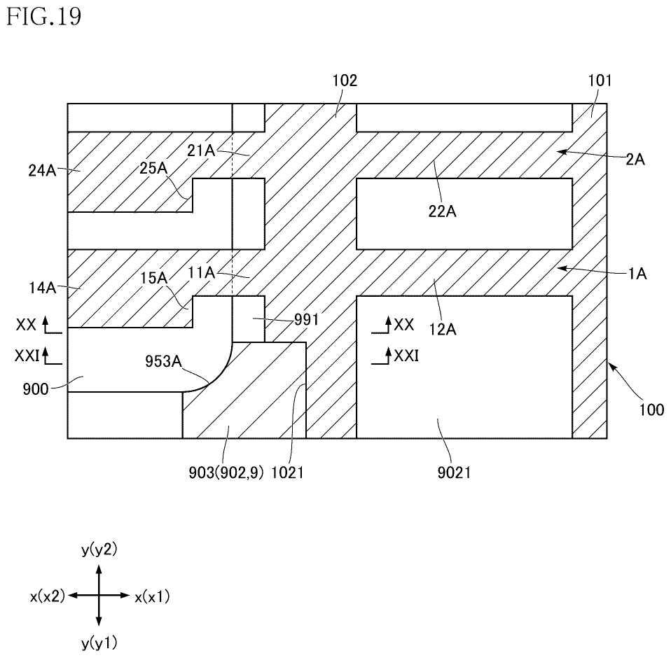

The mold fifth surface 95A is located between the mold third surface 93A and the mold fourth surface 94A as viewed in the first direction z. As shown in FIGS. 19 to 22, the mold fifth surface 95A include a mold first section 951A, a mold second section 952A, and a mold third section 953A. The mold first section 951A, the mold second section 952A, and the mold third section 953A are the surfaces for molding the resin first section 751A, the resin second section 752A, and the resin third section 753A, respectively. The mold first section 951A is connected to the mold first surface 91. The mold second section 952A is connected to the mold second surface 92. At least a portion of the mold third section 953A is inclined relative to the second direction x and the third direction y as viewed in the first direction z. In the illustrated example, the entire mold third section 953A is inclined relative to the second direction x and the third direction y as viewed in the first direction z. As viewed in the first direction z, the mold third section 953A may be a concave surface that is recessed outwardly in the second direction x and the third direction y. The mold third section 953A may be along the first direction z.

The mold 9 may additionally include a projection 903. The projection 903 is located between the first mold opposing surface 9011 and the second mold opposing surface 9021. In the illustrated example, the projection 903 is integral with the second mold 902 and protrudes from the second mold opposing surface 9021 toward the first side z1 in the first direction z. The mold third section 953A is included in the projection 903. As viewed in the first direction z, a portion of the projection 903 may be received within the recessed portion 1021.

The mold fifth surfaces 95B, 95C, and 95D may be similar in configuration to the mold fifth surface 95A.

As shown in FIG. 19, a clearance 991 is provided between the projection 903, the bar portion 102, and the first root portion 11A.

The length in the second direction x between the bar portion 102 and the cavity 900 (the mold third surface 93A or 93B) may be, but not limited to, from 100 to 500 μm, for example.

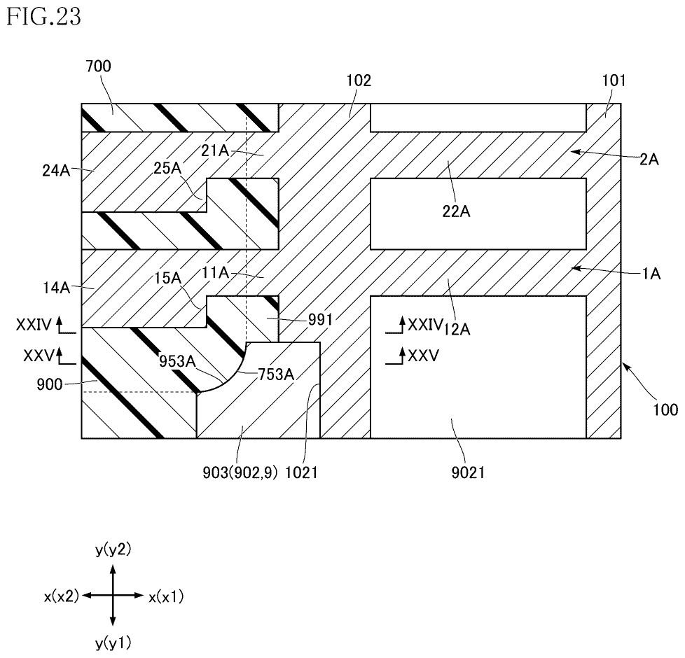

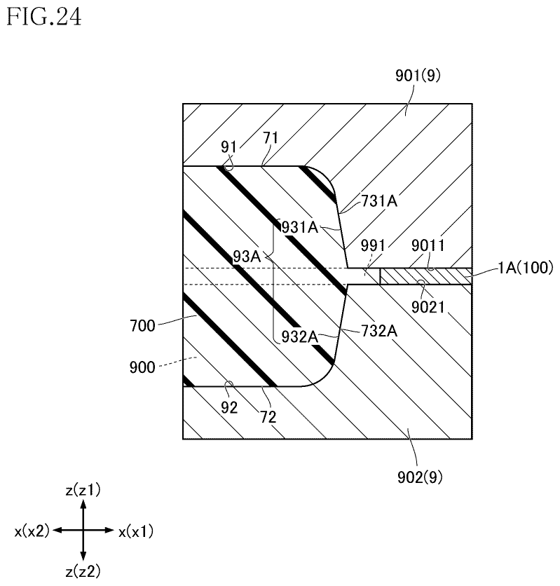

Subsequently, as shown in FIGS. 23 to 26, a resin material is injected to fill the cavity 900 and is allowed to harden. As a result, a resin intermediate 700 is formed. The material of the resin intermediate 700 is the same as the material of the sealing resin 7. The resin intermediate 700 includes a portion that will be the sealing resin 7 and portions protruding therefrom in the second direction x and the third direction y. The protruding portions are formed as a result that some of the resin material flows in the second direction x or the third direction y into the space between the first mold opposing surface 9011 and the second mold opposing surface 9021. The resin material flowing in the second direction x is blocked by the bar portion 102 from flowing any further. Using the mold 9 having the configuration described above, the resin intermediate 700 may be formed with a resin first surface 71, a resin second surface 72, a resin fourth section 731A, a resin fifth section 732A, a resin fourth section 731B, a resin fifth section 732B, a resin seventh section 741A, a resin eighth section 742A, a resin seventh section 741B, a resin eighth section 742B, a resin fifth surface 75A, a resin fifth surface 75B, a resin fifth surface 75C and a resin fifth surface 75D.

Note that the mold fifth surface 95A may additionally include a mold first intermediate section 954A and a mold second intermediate section 955A as shown in FIG. 26. The mold first intermediate section 954A is located between the mold first section 951A and the mold third section 953A, facing toward the second side z2 in the first direction z. The mold first intermediate section 954A is a surface for molding the resin first intermediate section 754A. The mold second intermediate section 955A is located between the mold second section 952A and the mold third section 953A, facing toward the first side z1 in the first direction z. The mold second intermediate section 955A is a surface for molding the resin second intermediate section 755A. A configuration similar to the mold fifth surface 95A may also be applied to the mold fifth surfaces 95B, 95C, and 95D.

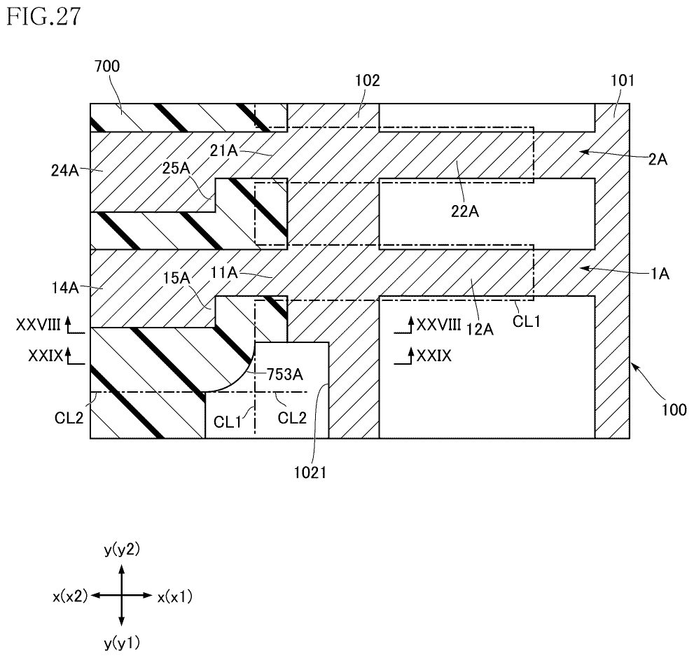

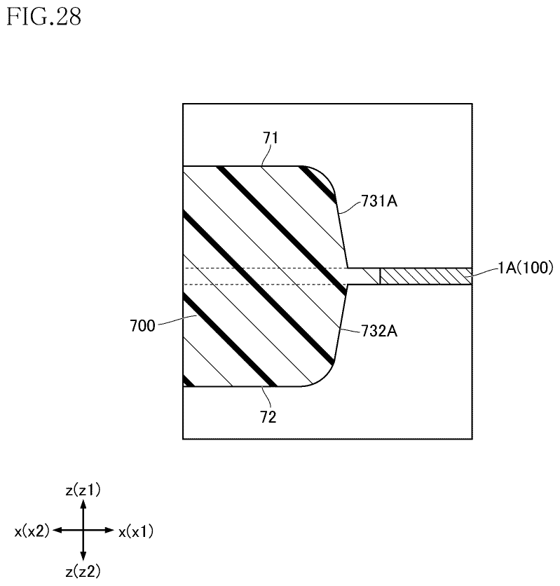

Subsequently, as shown in FIGS. 27 to 29, the mold 9 is removed from the lead frame 100. The subsequent step is to cut the lead frame 100 and the resin intermediate 700. The cutting step may include cutting along the cutting lines CL1 and CL2 shown in FIG. 27.

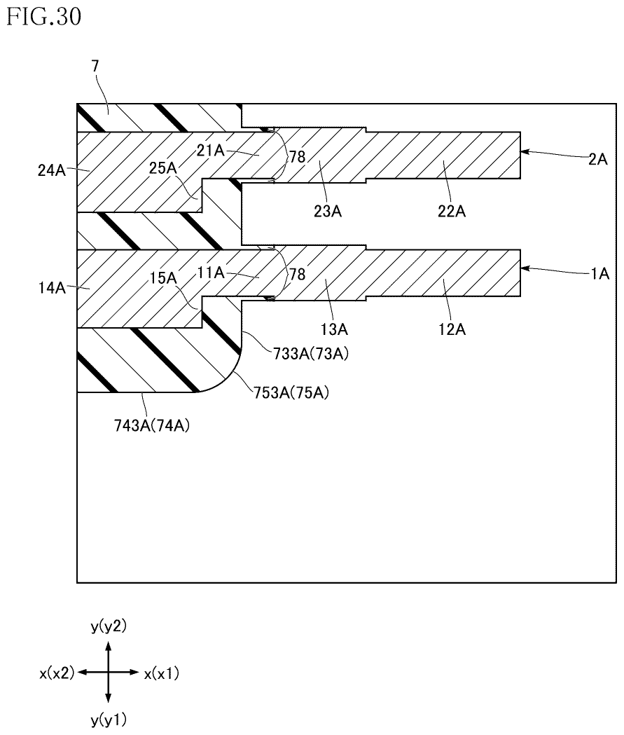

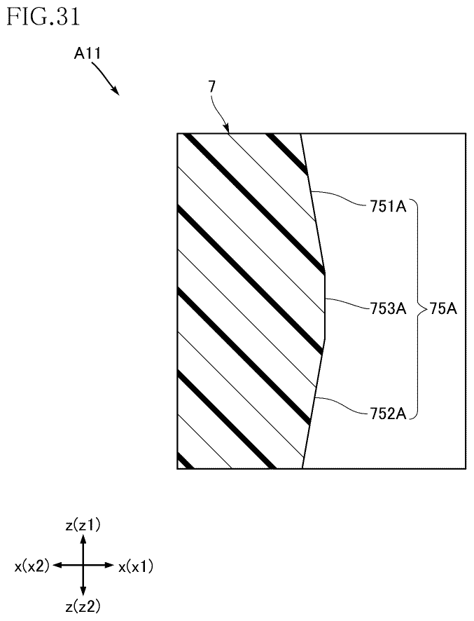

Cutting along the cutting line CLI separates the first leads 1A to 1D, the second lead 2A to 2D, and the leads 4A and 4B from the lead frame 100 and the bar portions 102. In addition, the portions of the resin intermediate 700 that extend in the second direction x between the first mold opposing surface 9011 and the second mold opposing surface 9021 are trimmed off. The distance between the cutting line CL1 and each of the first root portions 11A to 11D, the first end portions 12A to 12D, the second root portions 21A to 21D, the second end portions 22A to 22D, the root portions 41A and 41B, and the end portions 42A and 42B falls within a range of 0 to 100 μm, for example. By the cutting, the resin sixth section 733A and the resin sixth section 733B are formed as shown in FIG. 30. Additionally, a plurality of coating portions 78 are formed.

By cutting along the cutting line CL2 shown in FIG. 27, the portions of the resin intermediate 700 that extend in the third direction y between the first mold opposing surface 9011 and the second mold opposing surface 9021 are trimmed off. By the cutting, the resin ninth section 743A and the resin ninth section 743B are formed as shown in FIG. 30.

Subsequently, bending is applied to the first leads 1A to 1D, the second leads 2A to 2D, and the leads 4A and 4B as necessary. Through the above steps, the semiconductor device A1 is completed.

The following describes effects of the method for manufacturing the semiconductor device A1 and of the semiconductor device A1.

Consider a case different from the present embodiment in that the mold 9 does not have the mold third section 953A, for example. The resin intermediate 700 formed with such a mold may have a portion protruding between the first mold opposing surface 9011 and the second mold opposing surface 9021 in the second direction x toward the first side x1 or in the third direction y toward first side y1, in a region where the projection 903 is provided in the example shown in FIG. 23. When the protruding portion is cut in the step of cutting along the cutting lines CL1 and CL2 shown in FIG. 27, a burr may form on the sealing resin 7 in a shape defined by the extension lines of the resin sixth section 733A and the resin ninth section 743A as viewed in the first direction z. Such a burr may cause problems during packaging or transportation, such as snagging of the packaging materials of the semiconductor device. When a burr falls off during packaging or transportation, it could adversely affect the environment in which the semiconductor device is used.

In the present embodiment, the resin third section 753A is shaped by the mold third section 953A as shown in FIG. 23. Thus, the sealing resin 7 is formed as shown in FIGS. 11 and 12 and reduces the risk of forming a burr protruding between the resin sixth section 733A and the resin ninth section 743A in the second direction x toward the first side x1 or in the third direction y toward the first side y1. Reducing the formation of burrs can prevent associated problems during the transportation and usage of the semiconductor device A1.

The resin third section 753A has a finer surface roughness than the resin sixth section 733A and resin ninth section 743A. This prevents the resin third section 753A from snagging on packaging materials.

As shown in FIG. 23, a portion of the projection 903 is received within the recessed portion 1021. In other words, the projection 903 sticks out into the bar portion 102 as viewed in the first direction z. This configuration allows the size reduction of the first root portion 11A in the second direction x. Depending on a step performed for manufacturing the semiconductor device A1, the first root portion 11A can be coated with the coating portions 78 as shown in FIG. 11. The size reduction of the first root portion 11A in the second direction x allows the size reduction of the coating portions 78 in the second direction x. This reduces the risk of problems caused by peeling of the coating portion 78 or the like.

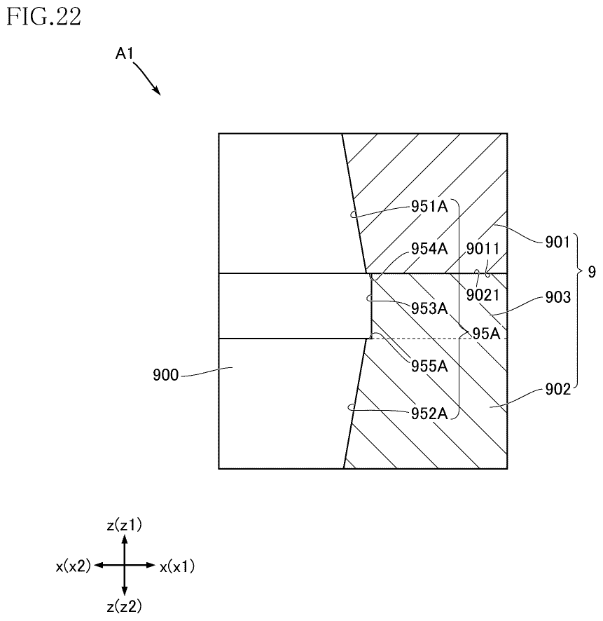

As shown in FIG. 22, the mold fifth surface 95A may include the mold first intermediate section 954A and the mold second intermediate section 955A. Even if the first mold 901 and the second mold 902 are slightly misaligned relative to each other, the mold first intermediate section 954A prevents the mold third section 953A from protruding in the second direction x toward the second side x2 beyond the edge of the mold first section 951A on the second side z2 in the first direction z. This configuration reduces the risk of unintended small projections forming on the sealing resin 7.

FIGS. 31 to 39 show variations of the present disclosure. In these figures, elements that are identical or similar to those of the embodiment describe above are indicated by the same reference numerals. Also, configurations of elements and components in each variation may be combined in any manner, provided that no technical inconsistencies arise.

FIG. 31 shows a variation of the resin fifth surface 75A. In a semiconductor device A11 of this variation, the resin third section 753A is continuous with the resin first section 751A and the resin second section 752A.

This variation reduces the possibility of burrs forming on the sealing resin 7. As can be understood from this variation, the resin fifth surface 75A may be configured without either or both of the resin first intermediate section 754A and the resin second intermediate section 755A.

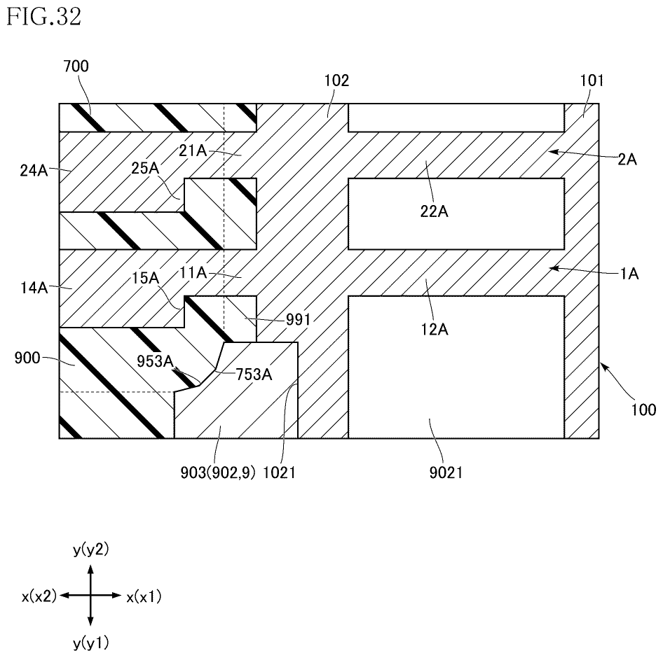

FIGS. 32 to 34 show variations of the resin third section 753A and the mold third section 953A.

In the variation shown in FIG. 32, the resin third section 753A and the mold third section 953A each have a polygonal shape composed of a plurality of planes.

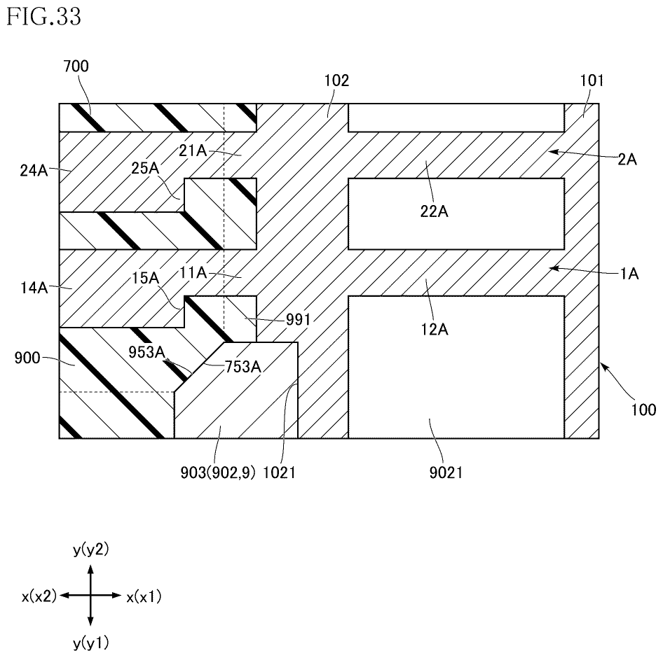

In the variation shown in FIG. 33, the resin third section 753A and the mold third section 953A are each composed of a flat plane inclined relative to the second direction x and the third direction y.

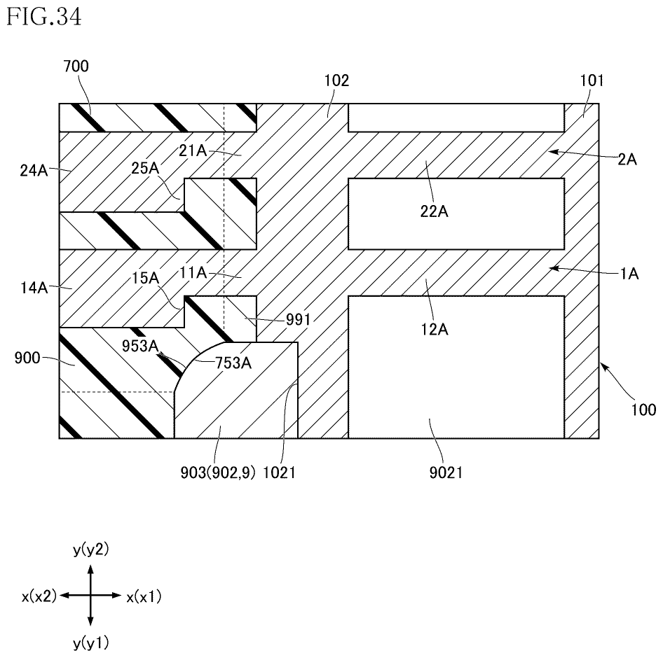

In the variation shown in FIG. 34, the resin third section 753A is a concave surface that is recessed inwardly in the second direction x and the third direction y, whereas the mold third section 953A is a convex surface that bulges inwardly in the second direction x and the third direction y.

This variations shown in FIGS. 32 to 34 reduce the possibility of burrs forming on the sealing resin 7. As can be understood from the variations shown in FIGS. 32 to 34, the resin third section 753A and the mold third section 953A are not limited to specific shapes, provided that the shape includes a portion inclined relative to the second direction x and the third direction y as viewed in the first direction z.

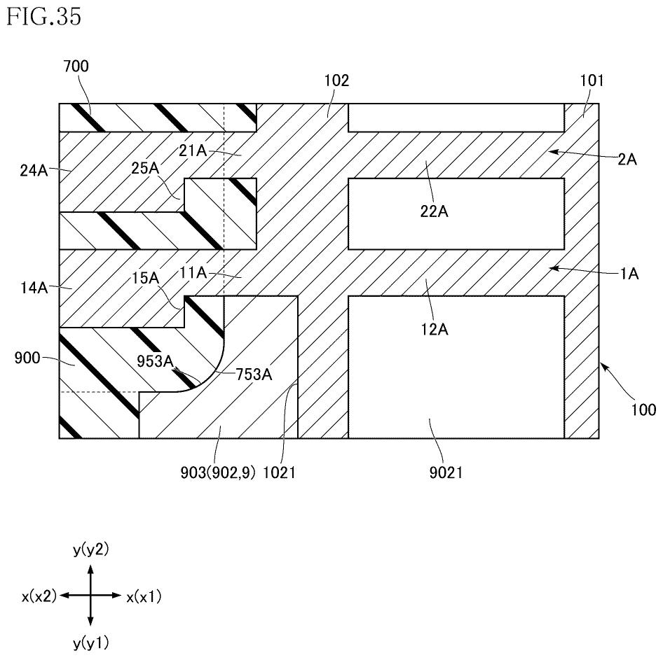

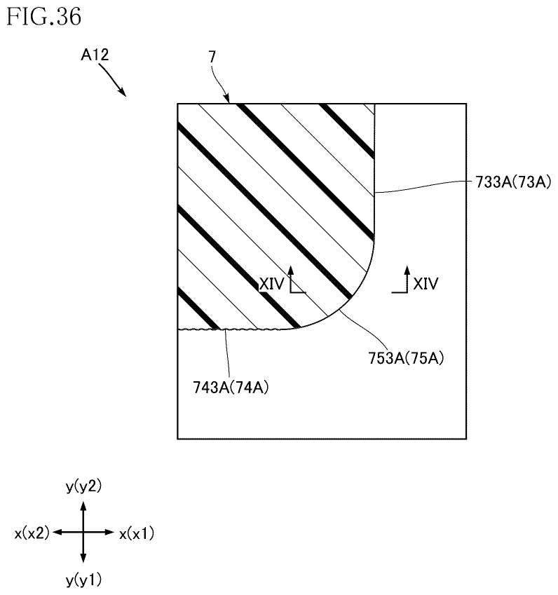

FIG. 35 shows a variation of the projection 903. In this variation, the clearance 991 described above is not present between the projection 903 and the first root portion 11A.

FIG. 36 shows a semiconductor device A12 manufactured through a method illustrated in FIG. 35. In the semiconductor device A12, the resin sixth section 733A is similar to the resin third section 753A in that it includes a flat portion shaped by a portion of the mold 9. The flat portion of the resin sixth section 733A has the same surface roughness as that of the resin third section 753A. In this variation, the resin sixth section 733A may have its maximum surface roughness at a portion between the first root portion 11A and the second root portion 21A. The portion of the resin sixth section 733A between the first root portion 11A and the second root portion 21A may be a surface created by cutting along the cutting line CL1.

This variation reduces the formation of burrs on the sealing resin 7. As can be understood from this variation, the resin sixth section 733A may include a portion having the surface roughness as that of the resin third section 753A. Note, however, that at least a portion of the resin sixth section 733A has a finer surface roughness than that of the resin third section 753A. Such a configuration may also apply to the resin ninth section 743A.

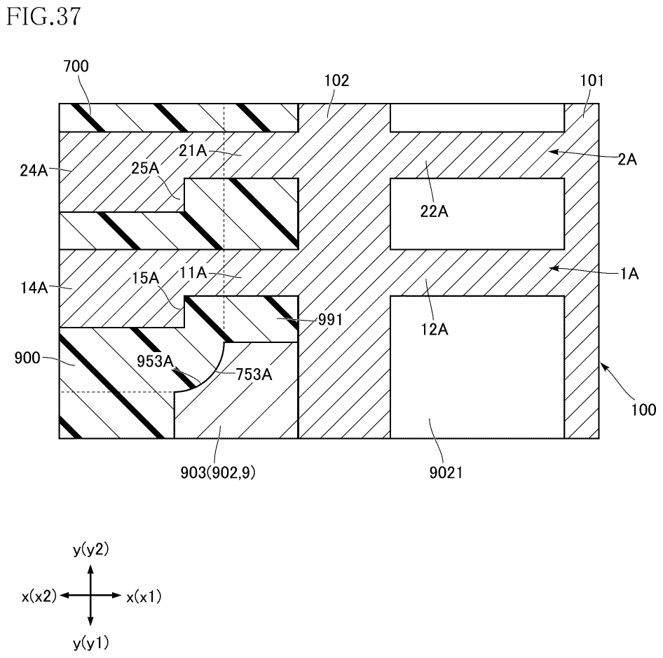

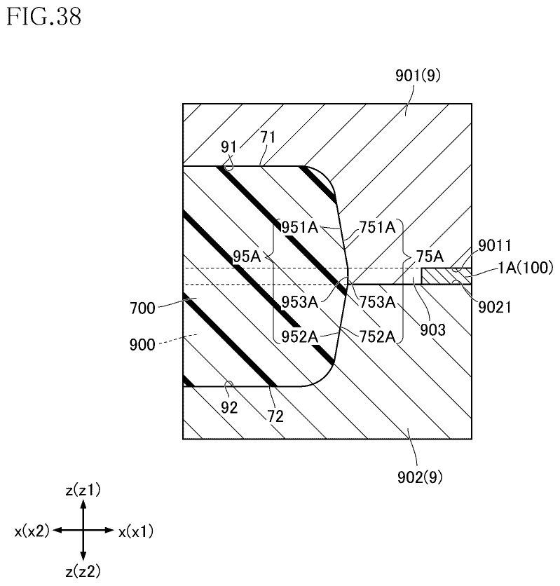

FIG. 37 shows a variation of the projection 903 and the bar portions 102. In this variation, the bar portions 102 are formed without the recessed portion 1021 described above. Thus, the projection 903 is not received within a recessed portion 1021 as viewed in the first direction z.

This variation reduces the formation of burrs on the sealing resin 7. As can be understood from this variation, the positional relation between the projection 903 and the bar portions 102 is not specifically limited.

FIG. 38 shows another variation of the projection 903. In this variation, the projection 903 is integral with the first mold 901 and protrudes from the first mold opposing surface 9011 toward the second side z2 in the first direction z.

This variation reduces the formation of burrs on the sealing resin 7. As can be understood from this variation, the configuration of the projection 903 is not specifically limited. For example, the projection 903 may be a component separate from the first mold 901 and the second mold 902.

The method for manufacturing a semiconductor device and the semiconductor device according to the present disclosure are not limited to the embodiment and variations described above. Various modifications in design may be made freely in the specific structure of each part of the s method for manufacturing a semiconductor device and the semiconductor device according to the present disclosure.

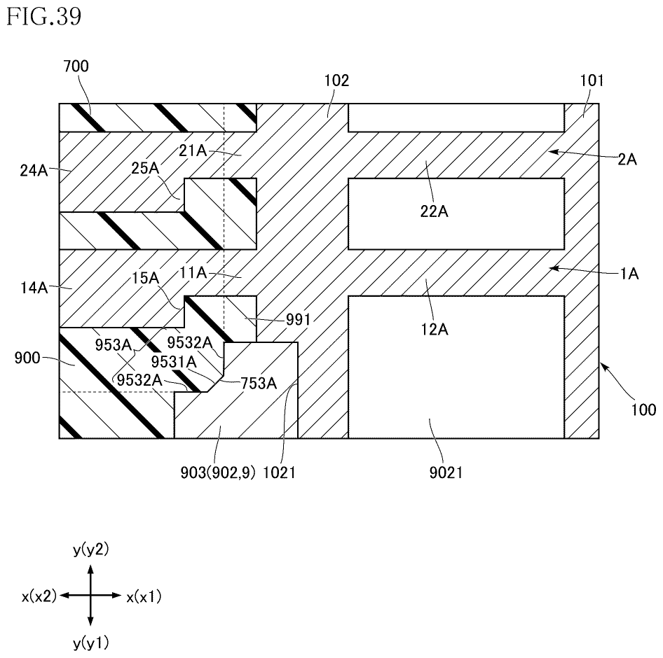

FIG. 39 shows a variation of the mold third section 953A. In this variation, the mold third section 953A includes an inclined section 9531A and two non-inclined sections 9532A. The inclined section 9531A is inclined relative to the second direction x and the third direction y. The two non-inclined sections 9532A are on the opposite sides of the inclined section 9531A and each parallel to either the second direction x or the third direction y. In this variation, the resin third section 753A is shaped by the inclined section 9531A.

This variation reduces the formation of burrs on the sealing resin 7. As can be understood from this variation, the configuration of the mold third section 953A is not specifically limited provided that at least a portion of the mold third section 953A is inclined relative to the second direction x and the third direction y.

### Clause 1

A method for manufacturing a semiconductor device (A1), the method comprising:
mounting a semiconductor element (60) on a lead frame (100);
placing a mold (9) to position the semiconductor element (60) within a cavity (900) of the mold (9);
forming a resin intermediate (700) by introducing a resin material into the cavity (900) and hardening the resin material; and
cutting the lead frame (100) and the resin intermediate (700),
wherein the mold (9) includes:
a mold first surface (91) and a mold second surface (92) respectively located on a first side (z1) and a second side (z2) in a first direction (z) that is a thickness direction of the lead frame (100);
a mold third surface (93A) facing in a second direction (x) perpendicular to the first direction (z) as viewed in the first direction (z);
a mold fourth surface (94A) facing in a third direction (y) perpendicular to the first direction (z) and the second direction (x) as viewed in the first direction (z); and
a mold fifth surface (95A) located between the mold third surface (93A) and the mold fourth surface (94A) as viewed in the first direction (z),
the mold fifth surface (95A) includes a mold first section (951A) connected to the mold first surface (91), a mold second section (952A) connected to the mold second surface (92), and a mold third section (953A) located between the mold first section (951A) and the mold second section (952A), and
at least a portion of the mold third section (953A) is inclined relative to the second direction (x) and the third direction (y) as viewed in the first direction (z).

### Clause 2

The method according to Clause 1, wherein the mold third section (953A) is a concave surface that is recessed outwardly in the second direction (x) and the third direction (y) as viewed in the first direction (z).

### Clause 3

The method according to Clause 1 or 2, wherein the mold (9) includes a first mold opposing surface (9011) and a second mold opposing surface (9021) respectively located on the first side (z1) and the second side (z2) in the first direction (z),
the first mold opposing surface (9011) and the second mold opposing surface (9021) sandwich the lead frame (100) in the first direction (z), and
the mold third section (953A) is located between the first mold opposing surface (9011) and the second mold opposing surface (9021) in the first direction (z).

### Clause 4

The method according to Clause 3, wherein the mold third surface (93A) includes:
a mold fourth section (931A) connected to the mold first surface (91) and located on the first side (z1) in the first direction (z) with respect to the first mold opposing surface (9011); and
a mold fifth section (932A) connected to the mold second surface (92) and located on the second side (z2) in the first direction (z) with respect to the second mold opposing surface (9021), and
the cutting of the lead frame (100) and the resin intermediate (700) involves cutting a portion of the resin intermediate (700) that protrudes in the second direction (x) between the mold fourth section (931A) and the mold fifth section (932A).

### Clause 5

The method according to Clause 4, wherein the mold fourth surface (94A) includes:
a mold seventh section (941A) connected to the mold first surface (91) and located on the first side (z1) in the first direction (z) with respect to the first mold opposing surface (9011); and
a mold eighth section (942A) connected to the mold second surface (92) and located on the second side (z2) in the first direction (z) with respect to the second mold opposing surface (9021), and
the cutting of the lead frame (100) and the resin intermediate (700) involves cutting a portion of the resin intermediate (700) that protrudes in the third direction (y) between the mold seventh section (941A) and the mold eighth section (942A).

### Clause 6

The method according to any one of Clauses 3 to 5, wherein the lead frame (100) includes:
a first lead (1A) and a second lead (2A) each extending in the second direction (x) and located next to each other in the third direction (y); and
a bar portion (102) connecting the first lead (1A) and the second lead (2A) and extending in the third direction (y), and
the cutting of the lead frame (100) and the resin intermediate (700) involves cutting the bar portion (102).

### Clause 7

The method according to Clause 6, wherein the mold (9) further includes a projection (903) located between the first mold opposing surface (9011) and the second mold opposing surface (9021) in the first direction (z), the mold third section (953A) being included in the projection (903), and
the bar portion (102) includes a recessed portion (1021) that receives the projection (903) as viewed in the first direction (z).

### Clause 1-1

The method according to any one of Clauses 1 to 7, wherein an entirety of the mold third section (953A) is inclined relative to the second direction (x) and the third direction (y) as viewed in the first direction (z).

### Clause 8

A semiconductor device (A1) comprising:
a semiconductor element (60);
a first lead (1A); and
a sealing resin (7) covering the semiconductor element (60) and a portion of the first lead (1A),
wherein the sealing resin (7) includes:
a resin first surface (71) and a resin second surface (72) respectively facing toward a first side (z1) and a second side (z2) in a first direction (z);
a resin third surface (73A) facing in a second direction (x) perpendicular to the first direction (z) as viewed in the first direction (z);
a resin fourth surface (74A) facing in a third direction (y) perpendicular to the first direction (z) and the second direction (x) as viewed in the first direction (z); and
a resin fifth surface (75A) located between the resin third surface (73A) and the resin fourth surface (74A) as viewed in the first direction (z),
the resin fifth surface (75A) includes a resin first section (751A) connected to the resin first surface (71), a resin second section (752A) connected to the resin second surface (72), and a resin third section (753A) located between the resin first section (751A) and the resin second section (752A),
the resin third surface (73A) includes a resin fourth section (731A) connected to the resin first surface (71), a resin fifth section (732A) connected to the resin second surface (72), and a resin sixth section (733A) located between the resin fourth section (731A) and the resin fifth section (732A),
the resin fourth surface (74A) includes a resin seventh section (741A) connected to the resin first surface (71), a resin eighth section (742A) connected to the resin second surface (72), and a resin ninth section (743A) located between the resin seventh section (741A) and the resin eighth section (742A),
the resin third section (753A) is inclined relative to the second direction (x) and the third direction (y) as viewed in the first direction (z), and
a surface roughness of the resin third section (753A) is finer than a maximum surface roughness of the resin sixth section (733A) and a maximum surface roughness of the resin ninth section (743A).

### Clause 9

The semiconductor device (A1) according to Clause 8, wherein the resin third section (753A) is a convex surface that bulges outwardly in the second direction (x) and the third direction (y) as viewed in the first direction (z).

### Clause 10

The semiconductor device (A1) according to Clause 8 or 9, wherein the first lead (1A) protrudes from the resin sixth section (733A).

### Clause 11

The semiconductor device (A1) according to Clause 10, wherein the resin sixth section (733A) includes a portion located between the resin third section (753A) and the first lead (1A).

### Clause 12

The semiconductor device (A1) according to Clause 11, wherein the resin fifth surface (75A) includes:
a resin first intermediate section (754A) located between the resin first section (751A) and the resin third section (753A) and facing toward the first side (z1) in the first direction (z); and
a resin second intermediate section (755A) located between the resin second section (752A) and the resin third section (753A) and facing toward the second side (z2) in the first direction (z).

### Clause 13

The semiconductor device (A1) according to any one of Clauses 8 to 12, wherein the resin fourth section (731A), the resin fifth section (732A), the resin seventh section (741A), and the resin eighth section (742A) are inclined relative to the first direction (z).

### Clause 14

The semiconductor device (A1) according to any one of Clauses 8 to 13, wherein the sealing resin (7) contains a base material (701) and a plurality of particles of fillers (702), and the plurality of particles of filler (702) are exposed to an outside to a greater extent at the resin sixth section (733A) and the resin ninth section (743A) than at the resin third section (753A).

### Clause 15

The semiconductor device (A1) according to any one of Clauses 8 to 14, wherein a surface roughness of the resin first section (751A), the resin second section (752A), the resin fourth section (731A), the resin fifth section (732A), the resin seventh section (741A), and the resin eighth section (742A) is finer than a maximum surface roughness of the resin sixth section (733A) and a maximum surface roughness of the resin ninth section (743A).

### Clause 16

The semiconductor device (A1) according to any one of Clauses 8 to 15, wherein the semiconductor element (60) includes a first semiconductor element (61),
the semiconductor device (A1) further comprising:
a first island (3A) on which the first semiconductor element (61) is mounted and which is covered with the sealing resin (7); and
the first island that comprises two first leads (1A, 1B), and
the two first leads (1A, 1B) are connected to the first island (3A).

### Clause 17

The semiconductor device (A1) according to Clause 16, wherein the semiconductor element (60) includes a second semiconductor element (62),
the semiconductor device (A1) further comprising:
a second island (3B) on which the second semiconductor element (62) is mounted and which is covered with the sealing resin (7); and
the first lead that comprises two first leads (1C, 1C), and
the two first leads (1C, 1D) are connected to the second island (3B).

### Clause 18

The semiconductor device (A1) according to Clause 17, wherein the semiconductor element (60) includes an insulating element (63), and
the insulating element (63) is configured to transmit a signal between the first semiconductor element (61) and the second semiconductor element (62) in an insulated state.

### Clause 19

The semiconductor device (A1) according to any one of Clauses 8 to 18, wherein the first lead (1A) includes a first root portion (11A), a first end portion (12A), and a first widened portion (13A) that are exposed from the sealing resin (7),
the first root portion (11A) is joined to the resin sixth section (733A),
the first end portion (12A) is an extremity of the first lead (1A) in the second direction (x), and
the first widened portion (13A) is located between the first root portion (11A) and the first end portion (12A), and a dimension of the first widened portion (13A) in the third direction (y) is greater than a dimension of each of the first root portion (11A) and the first end portion (12A) in the third direction (y).

### Clause 20

The semiconductor device (A1) according to Clause 19, wherein the sealing resin (7) includes a coating portion (78) covering a side surface of the first root portion (11A) in the third direction (y).

### REFERENCE NUMERALS

A1, A11, A12: semiconductor device
1A, 1B, 1C, 1D: first lead
2A, 2B, 2C, 2D: second lead
3A: first island
3B: second island
4A, 4B: lead
7: sealing resin
9: mold
11A, 11B, 11C, 11D: first root portion
12A, 12B, 12C, 12D: first end portion
13A, 13B, 13C, 13D: first widened portion
14A, 14B, 14C, 14D: first connecting portion
15A, 15B, 15C, 15D: first stepped portion
21A, 21B, 21C, 21D: second root portion
22A, 22B, 22C, 22D: second end portion
23A, 23B, 23C, 23D: second widened portion
24A, 24B, 24C, 24D: second connecting portion
25A, 25B, 25C, 25D: second stepped portion
26A, 26B, 26C, 26D: second pad portion
31A: through-hole
41A, 41B: root portion
42A, 42B: end portion
43A, 43B: widened portion
44A, 44B: connecting portion
45A, 45B: stepped portion
46A, 46B: pad portion
60: semiconductor element
61: first semiconductor element
62: second semiconductor element
63: insulating element
71: resin first surface
72: resin second surface
73A: resin third surface
73B: resin third surface
74A: resin fourth surface
74B: resin fourth surface
75A: resin fifth surface
75B: resin fifth surface
75C: resin fifth surface
75D: resin fifth surface
78: coating portion
81, 82, 83, 84: wire
91: mold first surface
92: mold second surface
93A: mold third surface
93B: mold third surface
94A: mold fourth surface
94B: mold fourth surface
95A: mold fifth surface
95B: mold fifth surface
95C: mold fifth surface
95D: mold fifth surface
100: lead frame
101: frame portion
102: bar portion
141A, 141B, 141C, 141D: through-hole
611, 621: electrode
631: first electrode
632: second electrode
700: resin intermediate
701: base material
702: filler
731A, 731B: resin fourth section
732A, 732B: resin fifth section
733A, 733B: resin sixth section
741A, 741B: resin seventh section
742A, 742B: resin eighth section
743A, 743B: resin ninth section
751A, 751B, 751C, 751D: resin first section
752A, 752B, 752C, 752D: resin second section
753A, 753B, 753C, 753D: resin third section
754A: resin first intermediate section
755A: resin second intermediate section
900: cavity
901: first mold
902: second mold
903: projection
951A: mold first section
952A: mold second section
953A: mold third section
954A: mold first intermediate section
955A: mold second intermediate section
991: clearance
1021: recessed portion
9011: first mold opposing surface
9021: second mold opposing surface
CL1, CL2: cutting line
x: second direction
x1: first side
x2: second side
y: third direction
y1: first side
y2: second side
z: first direction
z1: first side
z2: second side

1. A method for manufacturing a semiconductor device, the method comprising:
mounting a semiconductor element on a lead frame;
placing a mold to position the semiconductor element within a cavity of the mold;
forming a resin intermediate by introducing a resin material into the cavity and hardening the resin material; and
cutting the lead frame and the resin intermediate,
wherein the mold includes:
a mold first surface and a mold second surface respectively located on a first side and a second side in a first direction that is a thickness direction of the lead frame;
a mold third surface facing in a second direction perpendicular to the first direction as viewed in the first direction;
a mold fourth surface facing in a third direction perpendicular to the first direction and the second direction as viewed in the first direction; and
a mold fifth surface located between the mold third surface and the mold fourth surface as viewed in the first direction,
the mold fifth surface includes a mold first section connected to the mold first surface, a mold second section connected to the mold second surface, and a mold third section located between the mold first section and the mold second section, and
at least a portion of the mold third section is inclined relative to the second direction and the third direction as viewed in the first direction.

2. The method according to claim 1, wherein the mold third section is a concave surface that is recessed outwardly in the second direction and the third direction as viewed in the first direction.

3. The method according to claim 1, wherein the mold includes a first mold opposing surface and a second mold opposing surface respectively located on the first side and the second side in the first direction,
the first mold opposing surface and the second mold opposing surface sandwich the lead frame in the first direction, and
the mold third section is located between the first mold opposing surface and the second mold opposing surface in the first direction.

4. The method according to claim 3, wherein the mold third surface includes:
a mold fourth section connected to the mold first surface and located on the first side in the first direction with respect to the first mold opposing surface; and
a mold fifth section connected to the mold second surface and located on the second side in the first direction with respect to the second mold opposing surface, and
the cutting of the lead frame and the resin intermediate involves cutting a portion of the resin intermediate that protrudes in the second direction between the mold fourth section and the mold fifth section.

5. The method according to claim 4, wherein the mold fourth surface includes:
a mold seventh section connected to the mold first surface and located on the first side in the first direction with respect to the first mold opposing surface; and
a mold eighth section connected to the mold second surface and located on the second side in the first direction with respect to the second mold opposing surface, and
the cutting of the lead frame and the resin intermediate involves cutting a portion of the resin intermediate that protrudes in the third direction between the mold seventh section and the mold eighth section.

6. The method according to claim 3, wherein the lead frame includes:
a first lead and a second lead each extending in the second direction and located next to each other in the third direction; and
a bar portion connecting the first lead and the second lead and extending in the third direction, and
the cutting of the lead frame and the resin intermediate involves cutting the bar portion.

7. The method according to claim 6, wherein the mold further includes a projection located between the first mold opposing surface and the second mold opposing surface in the first direction, the mold third section being included in the projection, and
the bar portion includes a recessed portion that receives the projection as viewed in the first direction.

8. A semiconductor device comprising:
a semiconductor element;
a first lead; and
a sealing resin covering the semiconductor element and a portion of the first lead,
wherein the sealing resin includes:
a resin first surface and a resin second surface respectively facing toward a first side and a second side in a first direction;
a resin third surface facing in a second direction perpendicular to the first direction as viewed in the first direction;
a resin fourth surface facing in a third direction perpendicular to the first direction and the second direction as viewed in the first direction; and
a resin fifth surface located between the resin third surface and the resin fourth surface as viewed in the first direction,
the resin fifth surface includes a resin first section connected to the resin first surface, a resin second section connected to the resin second surface, and a resin third section located between the resin first section and the resin second section,
the resin third surface includes a resin fourth section connected to the resin first surface, a resin fifth section connected to the resin second surface, and a resin sixth section located between the resin fourth section and the resin fifth section,
the resin fourth surface includes a resin seventh section connected to the resin first surface, a resin eighth section connected to the resin second surface, and a resin ninth section located between the resin seventh section and the resin eighth section,
the resin third section is inclined relative to the second direction and the third direction as viewed in the first direction, and
a surface roughness of the resin third section is finer than a maximum surface roughness of the resin sixth section and a maximum surface roughness of the resin ninth section.

9. The semiconductor device according to claim 8, wherein the resin third section is a convex surface that bulges outwardly in the second direction and the third direction as viewed in the first direction.

10. The semiconductor device according to claim 8, wherein the first lead protrudes from the resin sixth section.

11. The semiconductor device according to claim 10, wherein the resin sixth section includes a portion located between the resin third section and the first lead.

12. The semiconductor device according to claim 11, wherein the resin fifth surface includes:
a resin first intermediate section located between the resin first section and the resin third section and facing toward the first side in the first direction; and
a resin second intermediate section located between the resin second section and the resin third section and facing toward the second side in the first direction.

13. The semiconductor device according claim 8, wherein the resin fourth section, the resin fifth section, the resin seventh section, and the resin eighth section are inclined relative to the first direction.

14. The semiconductor device according to claim 8, wherein the sealing resin contains a base material and a plurality of particles of filler, and
the plurality of particles of filler are exposed to an outside to a greater extent at the resin sixth section and the resin ninth section than at the resin third section.

15. The semiconductor device according to claim 8, wherein a surface roughness of the resin first section, the resin second section, the resin fourth section, the resin fifth section, the resin seventh section, and the resin eighth section is finer than a maximum surface roughness of the resin sixth section and a maximum surface roughness of the resin ninth section.
